(19) United States
(12) Patent Application Publication
(10) Pub. No.: US 2015/0243910 A1
(43) Pub. Date: Aug. 27, 2015

(54) TRANSITION METAL COMPLEXES COMPRISING ASYMMETRIC TETRADENTATE LIGANDS

(71) Applicant: SOLVAY SA, Brussels (BE)

(72) Inventors: Luisa De Cola, Strasbourg (FR); Sebastian Duck, Munster (DE); Robert Cysewski, Pozman (PL); Han Yang Cheng, Munster (DE); Jean-Pierre Catinat, Waudrez (BE)

(21) Appl. No.: 14/424,673

(22) PCT Filed: Aug. 22, 2013
(86) PCT No.: PCT/EP2013/067494

§ 371 Date: Feb. 27, 2015

(30) Foreign Application Priority Data
Aug. 31, 2012 (EP) 12006201.3
Sep. 28, 2012 (EP) 12186562.0

(51) Int. Cl. H01L 51/00; C09K 11/06; C07F 15/00

(52) U.S. Cl. CPC H01L 51/0085; C07F 15/0033; C09K 11/06; H01L 51/5012

(57) ABSTRACT

Light emitting transition metal complexes comprising sub-units based on asymmetric tetradentate ligands comprising two different bidentate ligand units.

The present invention relates to light emitting transition metal complexes comprising asymmetric tetradentate ligands and their use for the manufacture of organic electronic devices.

US 2005/170206 discloses organic light emitting devices comprising transition metal complexes based on multidentate ligands. Symmetric tetradentate ligands wherein two 2-phenylpyridine ligand units are connected via a linker are mentioned. This reference mentions that multidentate ligands should improve the kinetic stability of the transition metal complexes manufactured using same compared to isolated bidentate ligands.

WO 2008/096609 discloses carbene ligand units suitable for manufacturing transition metal complexes with two identical bidentate carbene ligand units being connected through an alkylene bridge.

US 2008/286605 discloses a symmetrical N, N′,O,O′ dianionic tetradentate ligand resulting from the deprotonation of 2,2′-(2,2′-bipyridine-6,6′-diyl)diphenol and transition metal complexes derived therefrom (cpd. D-29, page 48).

WO 2006/061182 discloses platinum complexes with symmetrical tetradentate ligands which are composed of two identical bidentate ligand units linked through a linker.

US 2010/0171417 discloses platinum complexes with tetradentate ligands comprising two identical or two different bidentate ligand units as phosphorescent materials in combination with certain charge transport materials useful in the manufacture of organic electronic devices.

Today, various light-emitting devices are under active study and development, in particular those based on electroluminescence (EL) from organic materials.

As a first example, light emitting electrochemical cells (often referred to as LEEC or LEO) may be mentioned. LEECs are solid state devices which generate light from an electric current. LEECs are usually composed of two metal electrodes connected by an organic semiconductor containing mobile ions.

Aside from the mobile ions, the structure of LEECs is similar to a second group of light emitting organic electronic devices which are commonly referred to as organic light emitting diodes (OLEDs).

In the contrast to photoluminescence, i.e. the light emission from an active material as a consequence of optical absorption and relaxation by radiative decay of an excited state, electroluminescence (EL) is a non-thermal generation of light resulting from the application of an electric field to a substrate. In this latter case, excitation is accomplished by recombination of charge carriers of opposite signs (electrons and holes) injected into an organic semiconductor in the presence of an external circuit.

A simple prototype of an organic light-emitting diode (OLED), i.e. a single layer OLED, is typically composed of a thin film of an active organic material which is sandwiched between two electrodes, one of which needs to have a degree of transparency sufficient in order to observe light emission from the organic layer.

If an external voltage is applied to the two electrodes, charge carriers, i.e. holes, at the anode and electrons at the cathode are injected to the organic layer beyond a specific threshold voltage depending on the organic material applied. In the presence of an electric field, charge carriers move through the active layer and are non-radiatively discharged when they reach the oppositely charged electrode. However, if a hole and an electron encounter one another while drifting through the organic layer, excited singlet and triplet states, so-called excitons, are formed. Light is thus generated in the organic material from the decay of molecular excited states (or excitons). For every three triplet excitons that are formed by electrical excitation in an OLED, only one state with antiparallel spin, S=0 (singlet) exciton is created.

Many organic materials exhibit fluorescence (i.e. luminescence from a spin-allowed process) from singlet excitons; since this process occurs between states of same spin multiplicity it may be very efficient. On the contrary, if the spin multiplicity of an exciton is different from that of the ground state, then the radiative relaxation of the exciton is spin forbidden and luminescence will be slow and inefficient. Because the ground state is usually a singlet, decay from a triplet is spin-forbidden (different spin multiplicity) and efficiency of EL is very low. Thus the energy contained in the triplet states is mostly wasted.

Phosphorescence emission is a phenomenon of light emission in the relaxation process between two states of different spin multiplicity, often between a triplet and a singlet, but because the relaxation process is normally conducted by thermal deactivation, it is in many cases not possible to observe phosphorescence emission at room temperature. Characteristically, phosphorescence may persist for up to several seconds after excitation due to the low probability of the transition, in contrast to fluorescence which originates in the rapid decay.

The theoretical maximum internal quantum efficiency of light-emitting devices comprising light-emitting materials based on an emission phenomenon in the relaxation process from a singlet excited state, (i.e. fluorescence emission), is at maximum 25%, because in organic EL devices the ratio of the singlet to the triplet state in the excited state of light-emitting materials is always appr. 25:75. By using phosphorescence (emission from triplet states) this efficiency could be raised to the theoretical limit of 100%, thereby significantly increasing the efficiency of the EL device.

As mentioned above, it is difficult to get phosphorescence emission from an organic compound because of low probability of intersystem crossing and concurrent thermal deactivation of the triplet relaxation process. However, it has been found that the presence of heavy atoms favours spin orbit coupling and therefore intersystem crossing is enhanced. This is also true when organic ligands are coordinated to heavy metals, showing spin-orbit interaction resulting from the heavy metal atom effect.

The wavelength of the light emitted is governed by the structure and the combination of ligands in the transition metal complex.

One of the challenges still to be satisfactorily solved in organic light emitting devices is the availability of suitable transition metal complexes providing sufficient stability in operating devices on one hand and desired photoactive properties on the other hand.

Accordingly there is still a need for phosphorescent transition metal complexes having improved stability, especially those emitting in the blue region, to obtain highly efficient and long term stable devices. Furthermore, to realize large area display and lighting applications at low cost, it is of interest to develop new emitters with sufficient solubility in suitable solvents to enable processing from solution, such as roll-to-roll printing, as the majority of known phosphorescent emitters are not soluble enough in organic solvents.

It was thus an object of the present invention to provide new transition metal complexes comprising tetradentate ligands useful in the manufacture of organic light emitting devices.

This object has been achieved with the transition metal complexes in accordance with claim 1 with a subunit comprising an asymmetric tetradentate ligand.

Preferred embodiments of the present invention are set forth in the dependent claims and the detailed specification hereinafter.

The light emitting transition metal complexes in accordance with the present invention comprise a transition metal M with an atomic number of at least 40 and having a coordination number equal to six, preferably selected from Ir, Rh, Re, Os or Ru and particularly preferred Ir, and a subunit with an asymmetric tetradentate ligand comprising two different bidentate ligand units L¹ and L² and represented by general formula (1)

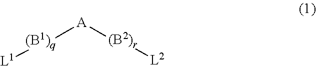

wherein q, and r, independent of one another are 0 or 1, preferably at least one of q and r being 1 and even more preferred q and r both being 1, the pending arm units B¹ and B², independent of one another are represented by general formula (2)

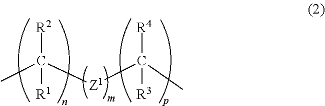

wherein Z¹ is a divalent group selected from the group consisting of —O—, —S—, —NR⁵—, —BR⁶—, —PR⁷—, —P(═O)R⁵—, —SiR⁹R¹⁰—, —N(R¹¹)—C(═O)—, —N═C(R¹²)—, —C(═O)—, —C═NR¹³—, —C(═S)— and —P(═S)(R¹⁴)—,
wherein R¹ to R¹⁴, which may be the same or different at each occurrence, are selected from hydrogen, halogen, NO₂, CN, NH₂, NHR′, N(R′)₂, B(OH)₂, B(OR′)₂, CHO, COOH, CONH₂, CON(R′)₂, CONHR′, SO₃H, C(═O)R′, P(═O)(R′)₂, S(═O)R′, S(═O)₂R′, P(R′)₃⁺, N(R′)₃⁺, OR′, SR′ and alkyl, haloalkyl, aryl, aralkyl or heteroaryl groups with R′ being selected from hydrogen, alkyl, aralkyl, aryl and heteroaryl groups
n, m and p, independently of one another, are integers of from 0 to 8, the sum of n+m+p being at least 1, and
wherein at least one of the L¹ and L² bidentate ligand units is represented by formula (3),

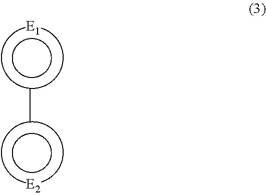

wherein
E₁ represents a nonmetallic atom group required to form a 5- or 6-membered heteroaromatic ring, optionally condensed with additional aromatic moieties or non aromatic cycles, said ring optionally having one or more substituents, optionally forming a condensed structure with the ring comprising E₂, and
E₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E₁, and
wherein the ring E₁ is bound to the transition metal via a neutral donor atom which is a carbon in the form of a carbene or a heteroatom, preferably a nitrogen atom, and the ring E₂ is bound to the transition metal through a carbon atom having formally a negative charge or through a nitrogen atom having formally a negative charge and wherein bivalent linking central scaffold A is selected from compounds of general formulae (4) to (7)

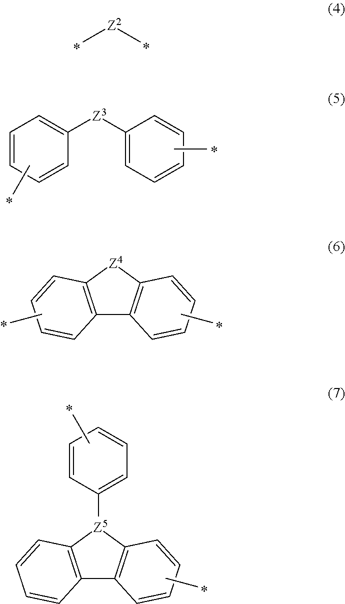

wherein
Z² is CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te or a substituted or unsubstituted 5- or 6-membered carbocyclic, aromatic or heteroaromatic ring; preferably Z² is CR₂, RN, —O—, —S—, RB, RP, RP(O), SiR₂ or a substituted or unsubstituted 5- or 6-membered carbocyclic, aromatic or heteroaromatic ring.

In accordance with an embodiment of the present invention, Z² is preferably a substituted or unsubstituted 5- or 6-membered carbocyclic, aromatic or heteroaromatic ring (which may carry substituents other than hydrogen). The heterocyclic rings may comprise one or more heteroatoms, preferably selected from O, N, S, P and Si, with 0, N and S being particularly preferred.

In accordance with another preferred embodiment Z² is a substituted or unsubstituted 5- or 6-membered carbocyclic, aromatic or heteroaromatic ring (which may carry substituents other than hydrogen) selected from the group consisting of

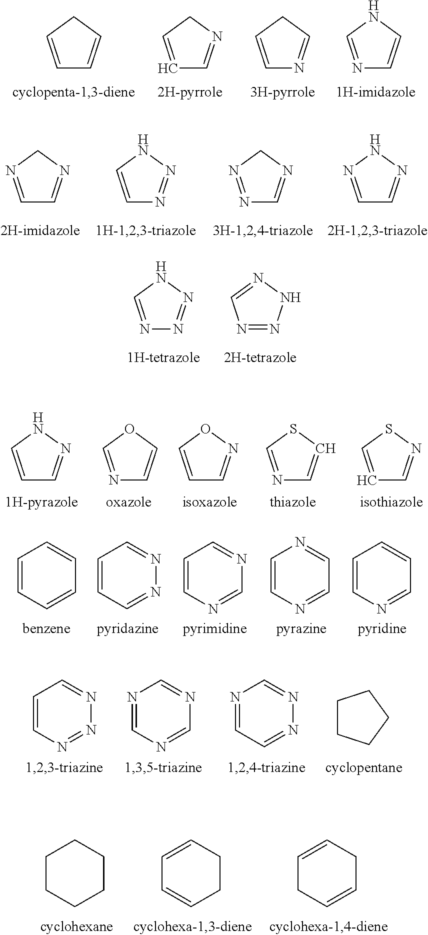

6-membered carbocyclic, aromatic or heteroaromatic rings being preferred, in particular Z² is a cyclohexane ring, a benzene ring. a pyridine ring, a pyrimidine ring, a 1,3,5- or 1,2,3-triazine ring,
Z³ and Z⁴ are CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te, preferably Z³ and Z⁴ are CR₂, NR, —O—, —S—, RB, RP, RP(O) or SiR₂; particularly preferred Z³ is CR₂, NR, RB RP, RP(O) and SiR₂, particularly preferred Z⁴ is CR₂, NR, O, S and SiR₂.
Z⁵ is CR, N, RN⁺, B, RB⁻, P, P(O), SiR, Al, RAl⁻, As, As(O), Sb, Sb(O), Bi, Bi(O), preferably CR, N, B, P, P(O) and SiR and
R, which may be the same or different at each occurrence, is selected from the group consisting of hydrogen, alkyl, haloalkyl, aralkyl, aryl and heteroaryl.

Preferred alkyl groups R which includes cycloalkyl groups are C₁ to C₂₀, preferably C₁ to C₁₀ and particularly preferably C₁ to C₆ alkyl groups, most preferred being methyl, ethyl, i-propyl, n-propyl, n-, i- and t-butyl, cyclopentyl, cyclohexyl and C₁₀ adamantyl groups.

Preferred haloalkyl groups R are based on the preferred alkyl groups defined above, wherein one or more of the hydrogen atoms have been replaced by one or more halogen atoms. Accordingly, preferred haloalkyl groups are based on C₁ to C₂₀, preferably C₁ to C₁₀ and particularly preferably C₁ to C₆ alkyl groups, most preferred being methyl, ethyl, i-propyl, n-propyl, n-, i- and t-butyl, cyclopentyl, cyclohexyl and C₁₀ adamantyl groups.

Preferred aralkyl groups R comprise alkyl groups as defined before wherein one or more of the hydrogen atoms have been replaced by an aryl group, preferably as defined below. The total number of carbon atoms in the aralkyl groups is between 5 and 50, preferably between 6 and 35 and particularly preferred between 6 and 25 carbon atoms. One or more carbon atoms in the aryl rings may be replaced by a heteroatom, e.g. N, 0 or S.

Preferred aryl groups R are 5- or 6-membered aromatic ring systems, which may carry one or more substituents other than hydrogen. Two or more rings may be annealed to form condensed structures or two and more aryl groups may be connected through a chemical bond. Examples for preferred aryl groups are phenyl, naphthyl, biphenyl, triphenyl and anthracenyl.

Preferred heteroaryl groups R are ring systems as described above for aryl rings wherein one or more of the ring carbon atoms has been replaced by a heteroatom, preferably selected from N, O and S. Preferred heteroaryl groups R are based on rings selected from the group consisting of

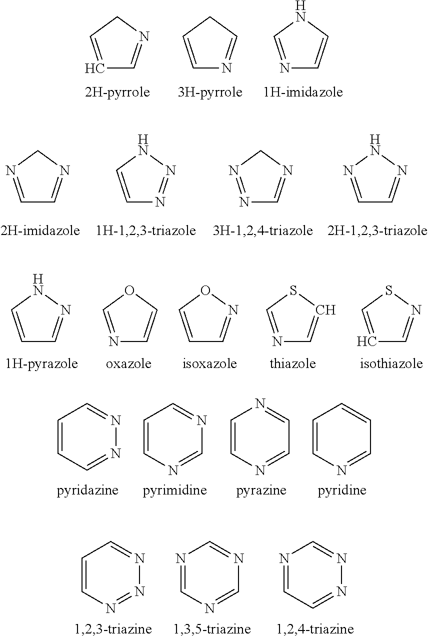

Preferred aryl and heteroaryl ring systems R comprise of from 1 to 50, preferably of from 1 to 30 and particularly preferable of from 1 to 20 carbon atoms.

In yet another preferred embodiment, central scaffold A comprises a moiety which is known to make part of a host or a hole or electron transport materials used in OLEDs. Such preferred moeties are pyridine, pyrimidine, triazine, carbazole, dibenzofuran and dibenzothiophene heteroaryl ring. Other preferred moieties correspond to triphenylamine, triphenylsilyl, triarylboron and phosphine oxide groups.

In the formulae (4) to (7) given above * denotes the two bonding sites of the bivalent central scaffold A through which bidentate ligand units L¹ and L² are bonded either directly or through arm units B¹ and B² (q and r being 1 in this case).

A is particularly preferably a CR₂, RN, —O—, —S—, RB, RP, RP(O), SiR₂ group or a five or six membered carbocyclic, aromatic or heteroaromatic ring in which the arm units B₁ and B₂, if present, may be attached to the ring in any combination of positions, A represents particularly preferably CR₂, RN, RB, RP(O), SiR₂ group or a five or six membered ring system selected from the group consisting of

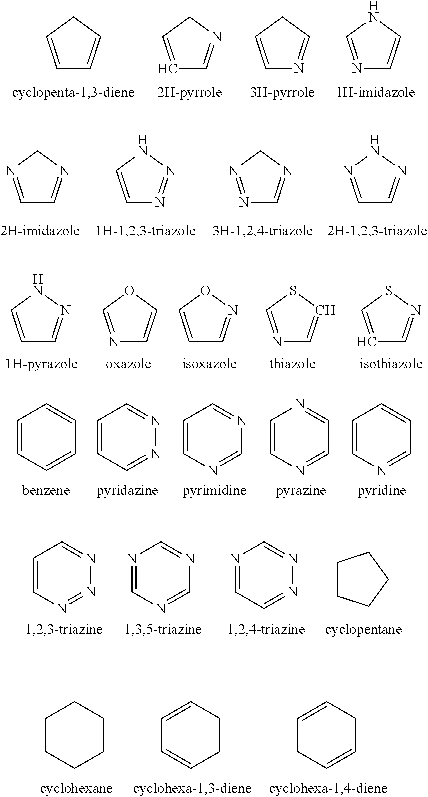

In accordance with a further preferred embodiment A is a six membered carbocyclic, aromatic or heteroaromatic ring, in particular a cyclohexane ring, a benzene ring, a pyridine ring, a pyrimidine ring, a 1,3,5- or 1,2,3-triazine ring to which arm units B¹ and B² (if present), respectively L¹ and L² bidentate ligand units are preferably bound in 1,3 meta position to each other.

In still another preferred embodiment, arm units B¹ and B² (if present) respectively L¹ and L² bidentate ligand units are bound in 1,4 para position to each other of an aryl or heteroaryl ring, in particular of a cyclohexane ring, a benzene ring, a pyridine ring, a pyrimidine ring, a 1,3,5- or 1,2,3-triazine ring

The bonding of arm units B¹ and B² respectively L¹ and L² bidentate ligand units in 1,2 ortho position to each other is less preferred compared to 1,3 and 1,4-bonding for sterical reasons.

In accordance with another preferred embodiment, bivalent central scaffold A is selected from formula (5) in which the arm units B¹ and B² (if present) or the two ligand units L¹ and L² directly are attached to the phenyl rings in any combination of positions, as shown in the formula.

In accordance with a further preferred embodiment, A is selected from formula (5) wherein the arm units B¹ and B² (if present) or the two ligand units L¹ and L² directly are attached to the phenyl rings in para positions to the Z³ atom.

In accordance with another preferred embodiment, bivalent central scaffold A is selected from formulae (6) to (7) in which the arm units B¹ and B² (if present) or the two ligand units L¹ and L² directly are attached to the benzene rings in any combination of positions, as shown in the formulae. In accordance with a further preferred embodiment, A is selected from formulae (6) to (7) wherein the arm units B¹ and B² (if present) or the two ligand units L¹ and L² directly are attached to the benzene rings in para positions to the Z⁴ and Z⁵ atoms.

The arm units B¹ and B², which may be the same or different at each occurrence, may be any divalent bridging group represented by formula (2) given above.

Preferred groups B¹ and B² are selected from alkylene groups having of from 1 to 8 carbon atoms, i.e. groups of formula (2) wherein m and p are zero and n is an integer of from 1 to 8, particularly preferred from alkylene groups having of from 2 to 4 carbon atoms.

In certain cases it has proven to be advantageous if, in addition to an alkylene chain an element Z¹ is present (i.e. m is 1), which in this case is preferably —O—, —S—, —NR⁵—, —BR⁶—, —PR⁷—, —P(═O)R⁸—, —SiR⁹R¹⁰—, —N(R¹¹)—, —C(═O)—, —N═C(R¹²)—, —C(═O)—, —C═NR¹³— with R⁵ to R¹³ as defined hereinabove, in particular —O—, —S—, —NR⁵—, —N(R¹¹)—C(═O)—, —N═C(R¹²)—, —C(═O)—, —C═NR¹³— with R⁵ to R¹³ as defined hereinabove.

In accordance with another preferred embodiment B¹ and/or B² represent a group of formula (2) with n being an integer of from 1 to 8, m being 1 and p being an integer of from 1 to 8, i.e. wherein two alkylene groups are separated by a group Z¹ as defined above.

In accordance with still another embodiment arm units B¹ and B² comprise a structural element —CH₂—NH—, —CH₂—CH₂—NH—, —CH₂—N(CH₃)—, —CH₂—NH—CH₂—, —N(CH₃)—CH₂, —CH₂—CH₂—NH—C(═O)—, —CH₂—NH—C(═O)— and the equivalent structural elements wherein one or more of the hydrogen atoms attached to carbon atoms are replaced by methyl or ethyl.

The sum of n+m+p is at least 1, preferably n and p independently of one another are integers of from 0 to 8, preferably of from 0 to 4 and m is preferably 0 or 1.

For the purpose of the present invention, the tetradentate ligands of the subunits of the light emitting transition metal complexes of the present invention are asymmetric due to the fact that they comprise two bidentate ligand units L¹ and L² which differ from each other, e.g. by their composition, their E₁ and E₂ ring structure, their nature and position of the linking between rings E₁ and E₂, their substituents or the positions at which these substituents are attached. For the purposes of the present invention tetradentate ligands which involve bidentate ligand units which are identical but are bound to central scaffold A or to pending arm units B¹ and B², if present, through different positions are not deemed to be asymmetric in accordance with the present invention. Tetradentate ligands which involve bidentate ligand units L¹ and L² showing any other difference are deemed to be asymmetric in accordance with the present invention.

The bidentate ligand units L¹ and L² may be bound to arm units B¹ and B², if present, or to central scaffold A through any position or in any manner which does not interfere with those positions through which the bidentate ligand units L¹ and L² are bound to the transition metal in the light emitting transition metal complexes in accordance with the present invention.

The asymmetric tetradentate ligands forming part of the subunit of the light emitting transition metal complexes in accordance with the present invention comprise two bidentate ligand units L¹ and L² which differ from each other as defined hereinbefore and which are linked to each other through central scaffold A and, if present to arm units B¹ and B² as defined hereinbefore.

In principle any ligand unit described in the prior art as bidentate ligand for transition metal complexes may be present in the light emitting transition metal complexes in accordance with the present invention. Thus, reference may be made to the prior art documents describing such ligands. At least one of the ligand units L¹ or L² is, however, represented by formula (3) as defined above.

In accordance with the present invention, the E₁ ring is bound to the transition metal via a neutral donor atom which is a carbon in the form of a carbene or a heteroatom, preferably a nitrogen atom, and ring E₂ is bound to the transition metal through a carbon atom having formally a negative charge or through a nitrogen atom having formally a negative charge. The E₁ ring is a 5 to 6-membered heteroaryl ring containing at least one donor nitrogen atom. Said ring may be un-substituted or substituted by substituents selected from the group consisting of halogen, NO₂, CN, NH₂, NHR¹⁵, N(R¹⁵)₂, B(OH)₂, B(OR¹⁵)₂, CHO, COOH, CONH₂, CON(R¹⁵)₂, CONHR¹⁵, SO₃H, C(═O)R¹⁵, P(═O)(R¹⁵)₂, S(═O)R¹⁵, S(═O)₂R¹⁵, P(R¹⁵)₃⁺, N(R¹⁵)₃⁺, OR¹⁵, SR¹⁵, Si(R¹⁵)₃, and alkyl, haloalkyl, alkenyl, alkynyl, arylalkyl, aryl and heteroaryl groups with R¹⁵ being selected from hydrogen, alkyl, aralkyl, aryl and heteroaryl groups and/or may form an annealed ring system with other rings selected from cycloalkyl, aryl and heteroaryl rings. Heteroaryl substituents may be preferably un-substituted or substituted carbazolyl or un-substituted or substituted dibenzofuranyl.

More particularly E₁ is a heteroaryl ring derived from the heteroarenes group consisting of 2H-pyrrole, 3H-pyrrole, 1H-imidazole, 2H-imidazole, 4H-imidazole, 1H-1,2,3-triazole, 2H-1,2,3-triazole, 1H-1,2,4-triazole, 1H-pyrazole, 1H-1,2,3,4-tetrazole, imidazol-2-ylidene, oxazole, isoxazole, thiazole, isothiazole, 1,2,3-oxadiazole, 1,2,5-oxadiazole, 1,2,3-thiadiazole, 1,2,5-thiadazole, pyridazine, pyridine, pyrimidine, pyrazine, 1,2,3-triazine, 1,2,4-triazine, 1,3,5-triazine, 1,2,3,4-tetrazine, 1,2,4,5-tetrazine and 1,2,3,5-tetrazine rings, which may be unsubstituted or substituted as defined above.

In accordance with a further preferred embodiment the ring E₂ is selected from the group consisting of substituted or un-substituted C₅-C₃₀ aryl and substituted or un-substituted C₂-C₃₀ heteroaryl groups, which E₂ group may be un-substituted or substituted by substituents selected from the group consisting of halogen, NO₂, CN, NH₂, NHR¹⁵, N(R¹⁵)₂, B(OH)₂, B(OR¹⁵)₂, CHO, COOH, CONH₂, CON(R¹⁵)₂, CONHR¹⁵, SO₃H, C(═O)R¹⁵, P(═O)(R¹⁵)₂, S(═O)R¹⁵, S(═O)₂R₁₅, P(R¹⁵)₃⁺, N(R¹⁵)₃⁺, OH, OR¹⁵, SR¹⁵, Si(R¹⁵)₃ and alkyl, haloalkyl, alkenyl, alkynyl, arylalkyl, aryl and heteroaryl groups as defined hereinabove with R¹⁵ being selected from hydrogen, alkyl, aralkyl, aryl and heteroaryl groups

E₁ and E₂ may be linked through a divalent linking group or through a covalent bond, which has proved to be advantageous in certain cases.

In the following a number of preferred embodiments of the present invention will be described in more detail.

According to a first preferred embodiment at least one of bidentate ligand units L¹ and L² is represented by formulae (8) to (10)

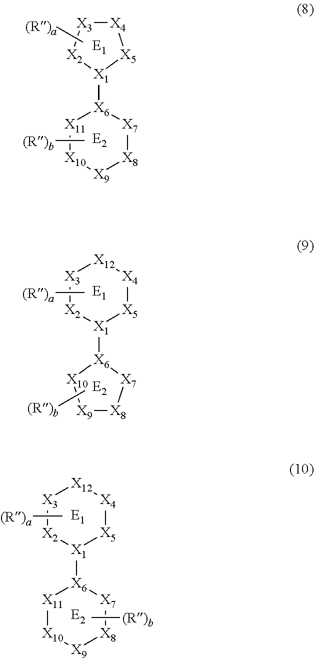

wherein
X₅ is a neutral donor atom via which the 5- or 6-membered heteroaromatic ring E₁ is bonded to the metal and which is a carbon in the form of a carbene or a heteroatom, preferably a nitrogen atom, X₇ is a carbon atom having formally a negative charge or a nitrogen atom having formally a negative charge via which the 5- or 6-membered aromatic or heteroaromatic ring E₂ is bound to the metal,
X₁, X₂, X₃, X₄, X₆, X₈, X₉, X₁₀, X₁₁, X₁₂ are independently from one other a carbon or a heteroatom, preferably a nitrogen atom, with the proviso that X₄ and X₁ are a nitrogen atom if X₅ corresponds to a carbon atom in the form of a carbene.

R″ and R′″, which may be the same or different at each occurrence, are hydrogen, halogen, NO₂, CN, NH₂, NHR⁵¹, N(R⁵¹)₂, B(OH)₂, B(OR⁵¹)₂, CHO, COOH, CONH₂, CON(R⁵¹)₂, CONHR⁵¹, SO₃H, C(═O)R⁵¹, P(═O)(R⁵¹)₂, S(═O)R⁵¹, S(═O)₂R⁵¹, P(R⁵¹)₃⁺, N(R⁵¹)₃⁺, OH, OR⁵¹, SR⁵¹, Si(R⁵¹)₃, a straight chain alkyl or alkoxy group having 1 to 20 carbon atoms or a branched or cyclic alkyl or alkoxy group with 3 to 20 carbon atoms, a haloalkyl group, a substituted or unsubstituted aromatic or heteroaromatic ring system having 5 to 50 ring atoms or a substituted or unsubstituted aryloxy, heteroaryloxy or heteroarylamino group having 5 to 50 ring atoms, two or more substituents R″ and R′″, either on the same or on different rings may define a further mono- or polycyclic, aliphatic or aromatic ring system with one another or with a substituent R⁵¹,

R⁵¹, which may be the same or different on each occurrence, may be hydrogen or a straight chain alkyl or alkoxy group having 1 to 20 carbon atoms or a branched or cyclic alkyl or alkoxy group with 3 to 20 carbon atoms, a substituted or unsubstituted aromatic or heteroaromatic ring system having 5 to 50 ring atoms or a substituted or unsubstituted aryloxy, heteroaryloxy or heteroarylamino group having 5 to 50 ring atoms, and a and b, independently from one another represent an integer in the range of from 0 to 3.

The two bidentate ligand units L¹ and L², independently from each other, may be bound to arms B¹ and B², if present, or to central scaffold A, through any position, including those from the R″ and R′″ substituents, or in any manner which does not interfere with those positions through which the bidentate ligand units are bound to the transition metal.

The bidentate ligand units corresponding to formulae (8) to (10) are preferably bound to arms B¹ and B², if present, or to central scaffold A, through their 6-membered E1 and E2 rings via those atoms which are located in para position to the E1-E₂ bond (X₁-X₆ bond), which correspond to X₉ atom in formula (8), to X₁₂ atom in formula (9) and to X₉ and X₁₂ atoms in formula (10). The bidentate ligand units L corresponding to formulae (8) to (10) are further preferably bound through their 6-membered E1 and E₂ rings via the atom which is located in meta position to the E1-E₂ bond (X₁-X₆ bond), which correspond to X₁₀ atom in formula (8), to X₃ atom in formula (9) and to X₃ and X₁₀ atoms in formula (10). Still another preferred linkage positions are those from 5-membered E1 and E2 rings corresponding to X₃ and X₄ atoms in formula (8) and to X₉ atom in formula (9).

In accordance with another preferred embodiment at least one of bidentate ligand units L¹ and L² is selected from the group consisting of phenylimidazole derivatives, phenylpyrazole derivatives, phenyltriazole derivatives, phenyltetrazole derivatives, 1-phenyl-imidazol-2-ylidene derivatives, 2-(1H-1,2,4-triazol-5-yl)pyridine derivatives, 2-(1H-pyrazol-5-yl)pyridine derivatives, phenylpyridine derivatives, phenylquinoline derivatives and phenylisoquinoline derivatives.

In yet another preferred embodiment of the present invention, at least one of the L¹ and L² bidentate ligand units is selected from the group consisting of compounds of formulae (11) to (15) which pertain to general formula (8)

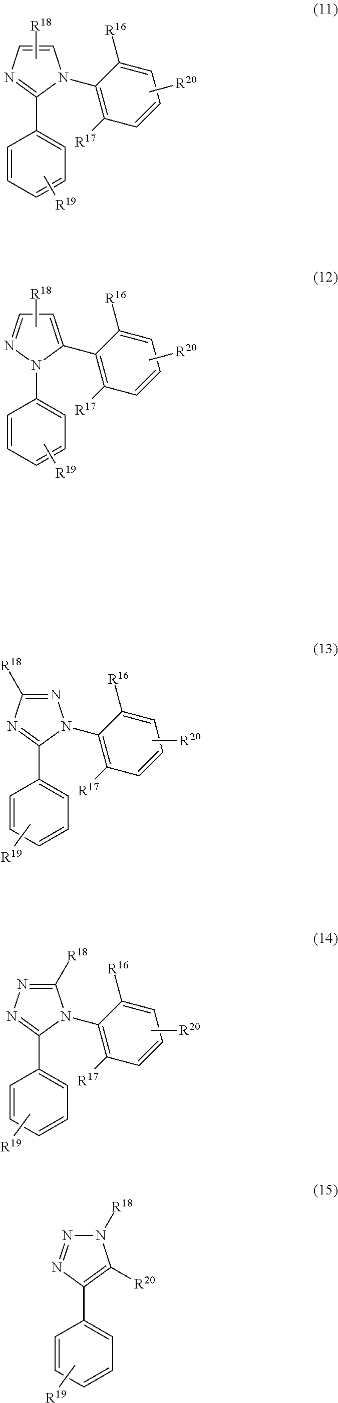

wherein R¹⁶ and R¹⁷ may be the same or different and are groups other than hydrogen, preferably selected from alkyl, haloalkyl, cycloalkyl, aryl and heteroaryl groups and more preferably from alkyl or haloalkyl groups and wherein R¹⁸ to R²⁰ may be the same or different and may be selected from the group consisting of hydrogen, halogen, NO₂, CN, NH₂, NHR²¹, N(R²¹)₂, B(OH)₂, B(OR²¹)₂, CHO, COOH, CONH₂, CON(R²¹)₂, CONHR²¹, SO₃H, C(═O)R²¹, P(═O)(R²¹)₂, S(═O)R²¹, S(═O)₂R²¹, P(R²¹)₃⁺, N(R²¹)₃⁺, OH, OR²¹, SR²¹, Si(R²¹)₃ and alkyl, haloalkyl, alkenyl, alkynyl, arylalkyl, aryl and heteroaryl group, with R²¹ being selected from hydrogen, alkyl, aralkyl, aryl and heteroaryl groups.

In accordance with yet another preferred embodiment, at least one of ligand units L¹ and L² is selected from the group consisting of compounds of formulae (16) to (26) which pertain to general formulae (11) and (12) (formulae 16 to 25) respectively to general formula (8) (formula 26)

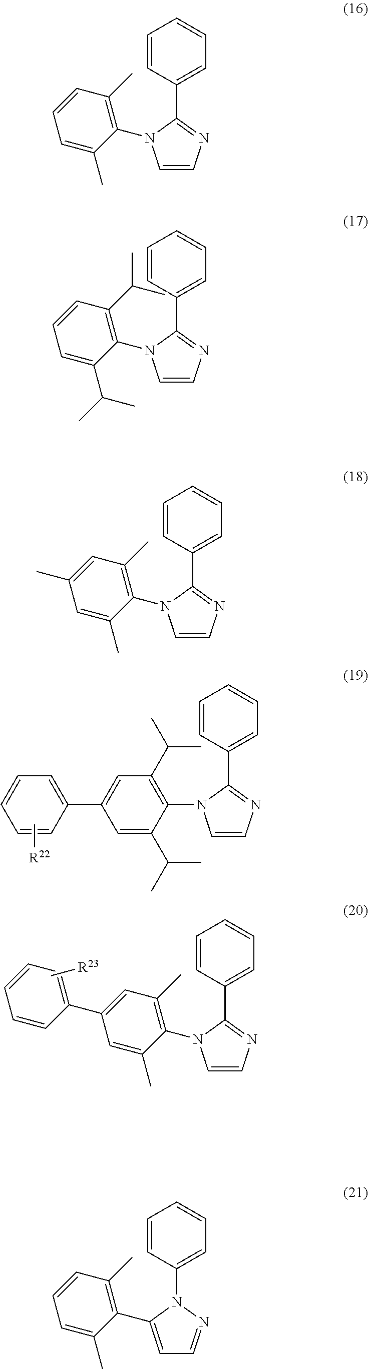

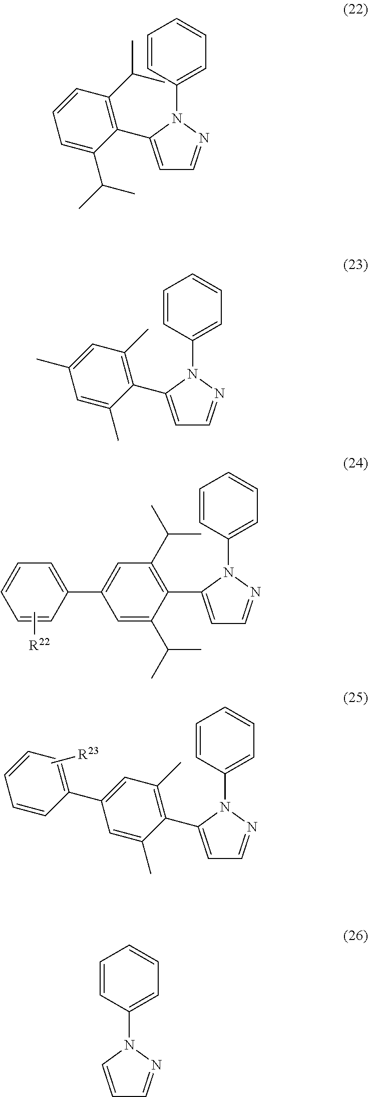

wherein R²² and R²³, independent of one another, are selected from hydrogen halogen, NO₂, CN, NH₂, NHR²⁴, N(R²⁴)₂, B(OH)₂, B(OR²⁴)₂, CHO, COOH, CONH₂, CON(R²⁴)₂, CONHR²⁴, SO₃H, C(═O)R²⁴, P(═O)(R²⁴)₂, S(═O)R²⁴, S(═O)₂R²⁴, P(R²⁴)₃⁺, N(R²⁴)₃⁺, OH, OR²⁴, SR²⁴, Si(R²⁴)₃ and alkyl, haloalkyl, alkenyl, alkynyl, arylalkyl, aryl and heteroaryl group, with R²⁴ being selected from hydrogen, alkyl, aralkyl, aryl and heteroaryl groups.

Still another preferred embodiment in accordance with the present invention is characterized by at least one of the L¹ to L² bidentate ligand units being selected from compounds of formulae (27) and (28) which pertain to general formula (8)

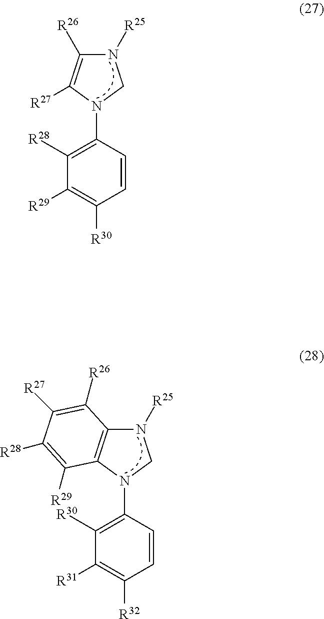

wherein R²⁵ to R³² may be the same or different at each occurrence and may be selected from the group consisting of hydrogen, halogen, NO₂, CN, NH₂, NHR³³, N(R³³)₂, B(OH)₂, B(OR³³)₂, CHO, COOH, CONH₂, CON(R³³)₂, CONHR³³, SO₃H, C(═O)R³³, P(═O)(R³³)₂, S(═O)R³³, S(═O)₂R³³, P(R³³)₃⁺, N(R³³)₃⁺, OH, OR³³, SR³³, Si(R³³)₃, and alkyl, haloalkyl, alkenyl, alkynyl, arylalkyl, aryl and heteroaryl groups, with R³³ being selected from hydrogen, alkyl, aralkyl, aryl and heteroaryl groups.

Further preferably, at least one of the L¹ to L² bidentate ligand units is selected from compounds of the general formulae (29) and (30) which pertain to general formula (9)

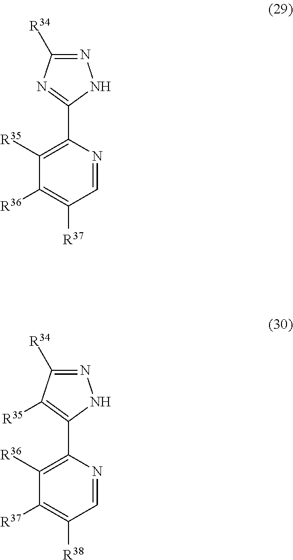

wherein R³⁴ to R³⁸ may be the same or different at each occurrence and may be selected from the group consisting of hydrogen, halogen, NO₂, CN, NH₂, NHR³⁹, N(R³⁹)₂, B(OH)₂, B(OR³⁹)₂, CHO, COOH, CONH₂, CON(R³⁹)₂, CONHR³⁹, SO₃H, C(═O)R³⁹, P(═O)(R³⁹)₂, S(═O)R³⁹, S(═O)₂R³⁹, P(R³⁹)₃⁺, N(R³⁹)₃⁺, OH, OR³⁹, SH, Si(R³⁹)₃, and alkyl, haloalkyl, alkenyl, alkynyl, arylalkyl, aryl and heteroaryl group, with R³⁹ being selected from hydrogen, alkyl, aralkyl, aryl and heteroaryl groups.

In accordance with still another preferred embodiment, at least one of the L¹ to L² bidentate ligand units is selected from compounds of the general formulae (31) to (33) which pertain to general formula (10)

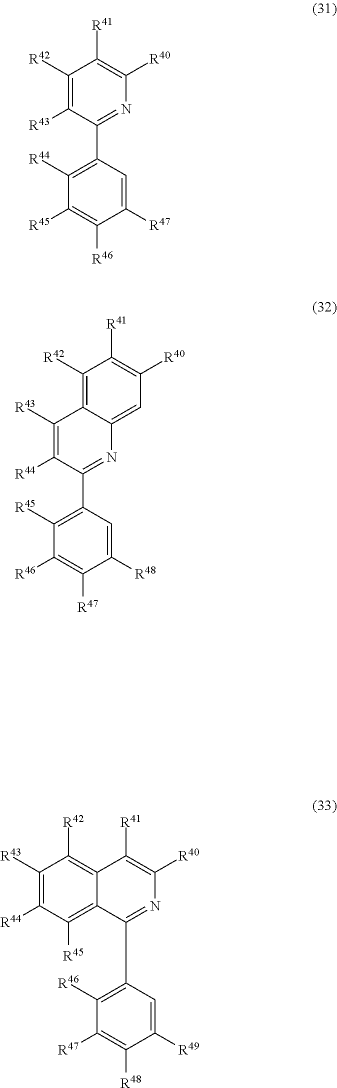

wherein R⁴⁰ to R⁴⁹ may be the same or different at each occurrence and may be selected from the group consisting of hydrogen, halogen, NO₂, CN, NH₂, NHR⁵⁰, N(R⁵⁰)₂, B(OH)₂, B(OR⁵⁰)₂, CHO, COOH, CONH₂, CON(R⁵⁰)₂, CONHR⁵⁰, SO₃H, C(═O)R⁵⁰, P(═O)(R⁵⁰)₂, S(═O)R⁵⁰, S(═O)₂R⁵⁰, P(R⁵⁰)₃⁺, N(R⁵⁰)₃⁺, OH, OR⁵⁰, SR⁵⁰, Si(R⁵⁰)₃ and alkyl, haloalkyl, alkenyl, alkynyl, arylalkyl, aryl and heteroaryl groups, with R⁵⁰ being selected from hydrogen, alkyl, aralkyl, aryl and heteroaryl groups.

As explained above, the asymmetric tetradentate ligands forming part of the light emitting transition metal complexes in accordance with the present invention comprise at least one bidentate ligand unit L¹ or L² which is represented by formula (3) and (8) to (33) above and particularly preferred both ligand units L¹ and L² are represented by formulae (3) and (8) to (33).

The bidentate ligand units L¹ and L² are selected in such a way that the complexes comprising a subunit with a tetradentate ligand involving these two ligands units emit in the desired range. Without wishing to be bound to any theory, it is believed that the emission color of the complexes comprising a tetradentate ligand composed of two bidentate ligand units L¹ and L² will be mainly dictated in a first approximation by the bidentate ligand units L¹ and L² which has the lowest triplet energy or which leads to the homoleptic complex, respectively [M(L¹)₃] and [M(L²)₃], emitting at the lower energy, provided that the other ligand(s) needed to complete the coordination sphere do(es)n't contribute to the photoactive properties of the complex.

One the two bidentate ligand units L¹ and L² may also be selected in order to impart to the complexes higher solubility in most organic solvents without changing its emission color e.g by selecting a bidentate ligand unit L² pertaining to the same family (phenylpyrazole, phenylimidazole . . . ) as the ligand unit L¹.

Tetradentate ligands of formulae (L34) to (L40) are preferred ligands for subunits of the light emitting transition metal complexes of the present invention, wherein both L¹ and L² are selected from compounds of formulae (8) to (33). For the sake of simplicity A has been chosen to represent a benzene ring and B¹ and B² are CH₂—CH₂ units linked to A in meta positions to each other in each of formulae L34 to L40; it is also possible, however, to choose A and B¹ and B² as well as the way the pending arms B¹ and B², if present, are linked to the central scaffold A from the broader definitions given hereinbefore. In the same way, for the sake of simplicity, it has been chosen to bind the pending arms B¹ and B² to the phenyl ring of the bidentate ligand units L¹ and L² in para position to the imidazole and/or pyrazole rings; it is also possible, however, to bind the bidentate ligand units L¹ and L² to pending arms B¹ and B², if present, or to central scaffold A through any position or in any manner which does not interfere with those positions through which the bidentate ligand units L¹ and L² of the asymmetric tetradentate ligand are bound to the transition metal.

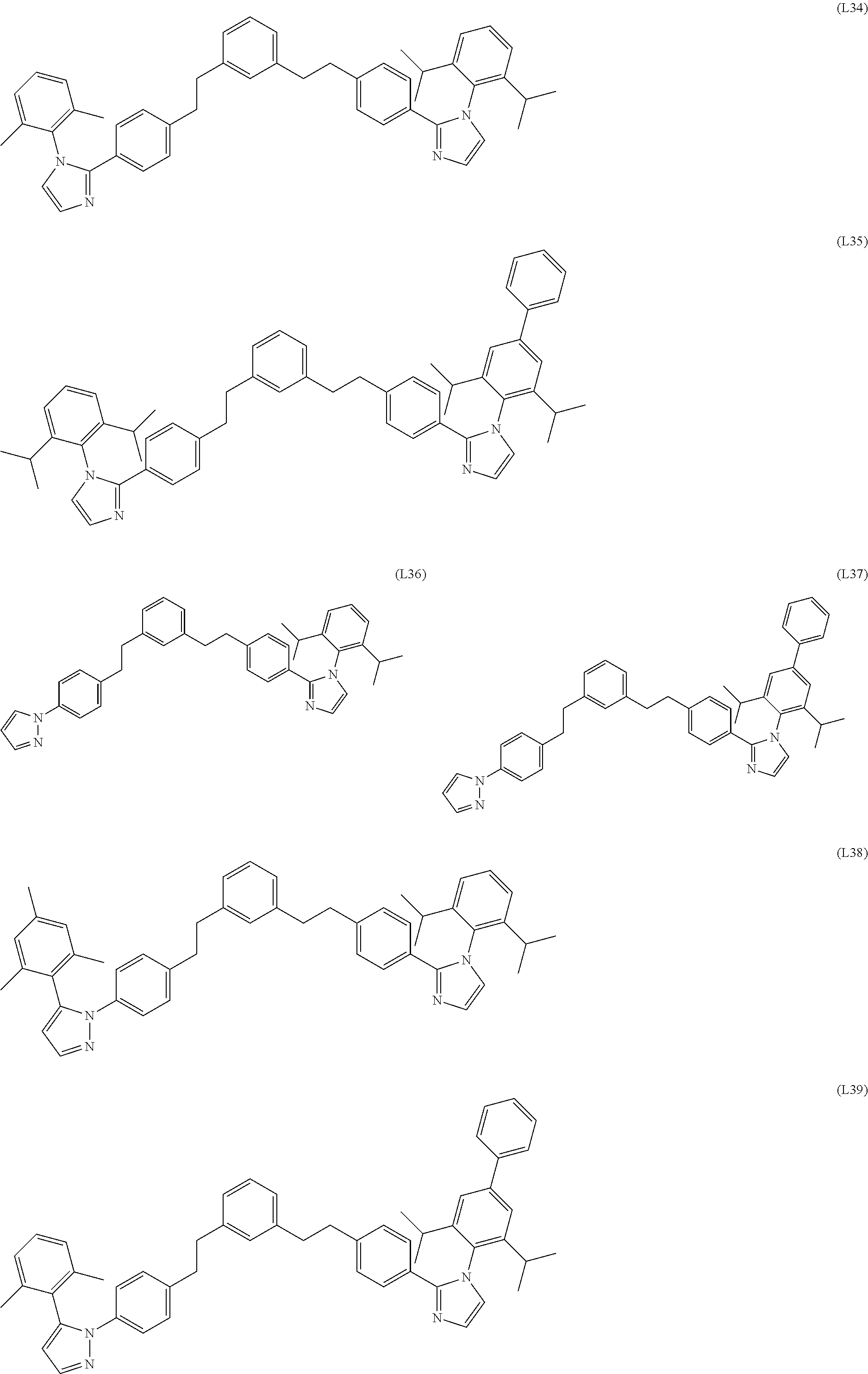

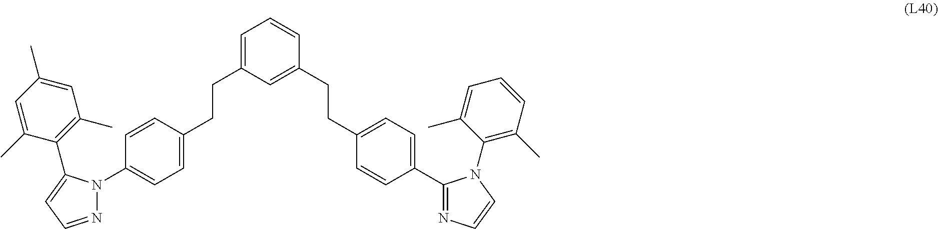

The subunit with the tetradentate ligands in accordance with the present invention may in another embodiment of the present invention comprise one ligand unit of formulae (3) and (8) to (33) and another bidentate ligand unit generally referred to in the prior art as “ancillary” ligands. In principle any ligand unit described in the prior art as bidentate ligand for transition metal complexes may be involved as “ancillary” ligand in the asymmetric tetradentate ligand in accordance with the present invention. Thus, reference may be made to the prior art documents describing such ligands. Just by way of example, acetylacetonate and picolinate ligand units may be mentioned here. The skilled person knows this type of ligand units which have been described in the literature.

The light emitting transition metal complexes in accordance with the present invention comprise other ligands in addition to the tetradentate ligands which may be mono- or bidentate, preferably bidentate.

Preferred light emitting transition metal complexes in accordance with the present invention may be characterized by the general formulae 41

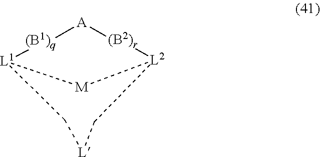

wherein L′ may be a bidentate ligand or a combination of two monodentate ligands, preferably a bidentate ligand and more preferably a bidentate ligand of formula (3′)

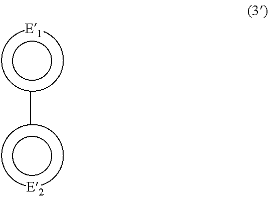

wherein
E′1 represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′2, and
E′2 represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′1, and
wherein the rings E′1 and E′2 could together form a polycyclic aliphatic, aromatic or heteroaromatic ring system and
wherein the ring E′1 is bound to the transition metal via a neutral donor atom which is a carbon in the form of a carbene or a heteroatom preferably a nitrogen atom and the ring E′2 is bound to the transition metal through a carbon atom having formally a negative charge or through a nitrogen atom having formally a negative charge.

Preferred additional bidentate ligands L′ in transition metal complexes of metals having a coordination number equal to six are ligands corresponding to the bidentate ligand units described hereinbefore for the asymmetric tetradentate ligands. Such additional ligand L′ may be identical to one of the ligand units L¹ and L² of the asymmetric tetravalent ligand or it may be different from either ligand unit L¹ and L² thus yielding transition metal complexes with three different bidentate ligand units coordinated to the metal.

Bidentate ligand L′ may also be selected from ligands of general formulae E3-SBF, E3-Ar1-SBF, E3-Open SBF and/or E3-Ar1-Open SBF wherein E₃ is a 5-membered heteroaryl ring, bound to the metal atom by covalent or dative bonds and containing at least one donor nitrogen atom, wherein said heteroaryl ring may be un-substituted or substituted by substituents selected from the group consisting of halogen, alkyl, alkoxy, amino, cyano, alkenyl, alkynyl, arylalkyl, aryl and heteroaryl group and/or may form an annealed ring system with other rings selected from cycloalkyl, aryl and heteroaryl rings;

Ar1 when present is bound to the metal atom by covalent or dative bonds and is selected from the group consisting of substituted or un-substituted C₆-C₃₀ arylene and substituted or un-substituted C₂-C₃₀ heteroarylene groups, which Ar1 group may be un-substituted or substituted by substituents selected from the group consisting of halogen, alkyl, alkoxy, amino, cyano, alkenyl, alkynyl, arylalkyl, aryl and heteroaryl groups; SBF represents 9,9′-spirobifluorenyl, Open SBF represents 9,9-diphenyl-9H-fluorenyl, in both cases un-substituted or substituted by substituents selected from the group consisting of halogen, alkyl, alkoxy, amino, cyano, alkenyl, alkynyl, arylalkyl, aryl and heteroaryl groups.

The additional ligand L′ may also be a bidentate ligand like picolinate, tetrakispyrazolylborate or acetylacetonate (generally referred to as ancillary ligands) or monodentate ligands as have been described in the literature as suitable for the manufacture of transition metal complexes.

In another preferred embodiment, the additional bidentate ligand L′ is selected in order to impart to the resulting complexes a higher solubility in most organic solvents.

The metal M in the light emitting transition metal complexes in accordance with the present invention represents a transition metal of atomic number of at least 40 and a coordination number equal to six, preferably Ir, Ru, Os, Re or Rh, most preferably Ir.

The light emitting materials in accordance with the present invention generally have a number of advantageous properties. The increased bulkiness of the tetradentate ligands as compared to bidentate ligands often leads to a reduced T-T annihilation at high current densities as well as to a reduced aggregate-induced concentration quenching at high doping levels, which in turn leads to an increased device efficiency.

Because of their expected less labile ligand system, complexes involving tetradentate ligands in accordance with the present invention are believed to show improved chemical, thermal, electrochemical and photochemical stability as compared to their bidentate ligands analogs. Higher device lifetimes are thus expected.

Given their more rigid structure with decreased vibrational and rotational freedom, complexes comprising tetradentate ligands in accordance with the present invention are expected to show less efficient non-radiative decay pathways and thus increased photoluminescence quantum yields and higher devices efficiencies than their bidentate analogs.

The emission color from the complexes involving asymmetric tetradentate ligands in accordance with the present invention could be tuned over a large range of wavelengths according to the selected bidentate ligand units L¹ and L² and the selected additional ligand L′. Without wishing to be bound by theory, it is believed that the emission color of the heteroleptic complexes comprising the tetradentate ligand with bidentate ligand units L¹ and L² and the additional bidentate ligand L′ will be mainly dictated in a first approximation by that of the bidentate ligands L¹, L² or L′ having the lowest triplet energy or leading to the homoleptic complex which emits at the lowest energy. So the “photoactive” ligand which is believed to contribute to the photoactive properties of the complexes comprising such ligands may be either the bidentate ligand unit L¹, the bidentate ligand unit L² or the additional bidentate ligand L′ according to the selection of the ligand units L¹ and L² and of the additional ligand L′ which has been made. So, making the choice of the ligand units L¹ and L² and of the additional ligand L′ in an appropriate way allows to select, on a very broad range of wavelengths, the emission color from the complexes involving asymmetric tetradentate ligands in accordance with the present invention.

So if one of the bidentate ligand units of the tetradentate ligand, e.g. L¹, is selected from the group consisting of compounds of formulae (11) to (26), blue emission would be expected provided L′ and L² are suitably selected from ligands having a triplet energy at least equal to that of bidentate ligand unit L¹ corresponding to compounds of formula (11) to (26). In the same way, if the additional bidentate ligand L′ is selected from the group consisting of compounds of formulae (11) to (26), blue emission would be expected provided L¹ and L² are suitably selected from ligands having a triplet energy at least equal to that of bidentate ligand L′ corresponding to compounds of formula (11) to (26). As mentioned before, especially blue-emitters need improvement in terms of lifetime and stability and the light-emitting materials in accordance with the present invention in preferred embodiments should provide significant advantages over the prior art in this regard as they should show a high efficiency while still providing a long lifetime.

More preferred blue emitting complexes in accordance with the present invention are those wherein both L¹ and L² bidentate ligand units of the asymmetric tetradentate ligand as well as the additional bidentate ligand L′ pertain to general formula (11) and are thus represented by following general formula (42):

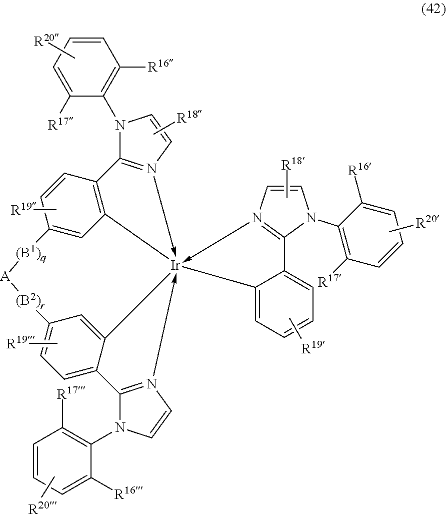

wherein A, B¹, B², q and r have the same meanings as in general formula (1) and wherein R₁₆′, R₁₆″, R₁₆′″ can have the same meanings as given for R¹⁶ in formula (11), R^{17′}, R¹⁷″, R¹⁷′″ can have the same meanings as given for R¹⁷ in formula (11), R₁₈′, R₁₈″, R₁₈′″ can have the same meanings as given for R¹⁸ in formula (11), R^{19′}, R¹⁹″, R¹⁹′″ can have the same meanings as given for R¹⁹ in formula (11) and R²⁰′, R²⁰″, R²⁰′″ can have the same meanings as given for R²⁰ in formula (11) and with the proviso that at least one of the following conditions is observed: R¹⁶″ is different from R¹⁶′″ or R¹⁷″ is different from R¹⁷′″ or R¹⁸″ is different from R¹⁸′″ or R¹⁹″ is different from R¹⁹′″ or R²⁰″ is different from R²⁰″. For the sake of simplicity it has been chosen in formula (42) to bind the pending arms B¹ and B² to the phenyl ring of the bidentate ligand units L¹ and L² in para position to the imidazole ring; it is also possible, however, to bind the bidentate ligand units L¹ and L² to pending arm B¹ and B², if present, or to central scaffold A through any position or in any manner which does not interfere with those positions through which the bidentate ligand units L¹ and L² are bound to the transition metal.

Blue emitting complexes in a still preferred embodiment in accordance with the present invention are selected from those corresponding to formulae (43), (43′), (44), (44′), (45), (45′), (46), (46′), (47) and (47′) wherein all the different R groups have the same meaning as defined in formula (42) and obey to the same conditions as indicated for formula (42). For the sake of simplicity central scaffold A has been chosen to represent a benzene ring and B¹ and B² are CH₂—CH₂ units which are linked to A in meta positions to each other in formulae (43), (44), (45), (46) and (47) and in para positions to each other in formulae (43′), (44′), (45′), (46′) and (47′); and it is also possible, however, to choose A, B¹ and B² from the broader definitions given hereinbefore as well as the way the pending arms B¹ and B², if present, are linked to the central scaffold A as indicated hereinbefore. Furthermore, for the sake of simplicity it has been chosen to bind the pending arms B¹ and B² to the phenyl ring of the bidentate ligand units L¹ and L² in para position to the imidazole ring in formulae (43), (44), (45), (46) and (47) and in meta position to the imidazole ring in formulae (43′), (44′), (45′) (46′) and (47′); it is also possible, however, to bind the bidentate ligand units L¹ and L² to pending arms B¹ and B², if present, or to central scaffold A through any position or in any manner which does not interfere with those positions through which the bidentate ligand units L′ and L² of the asymmetric tetradentate ligand are bound to the transition metal.

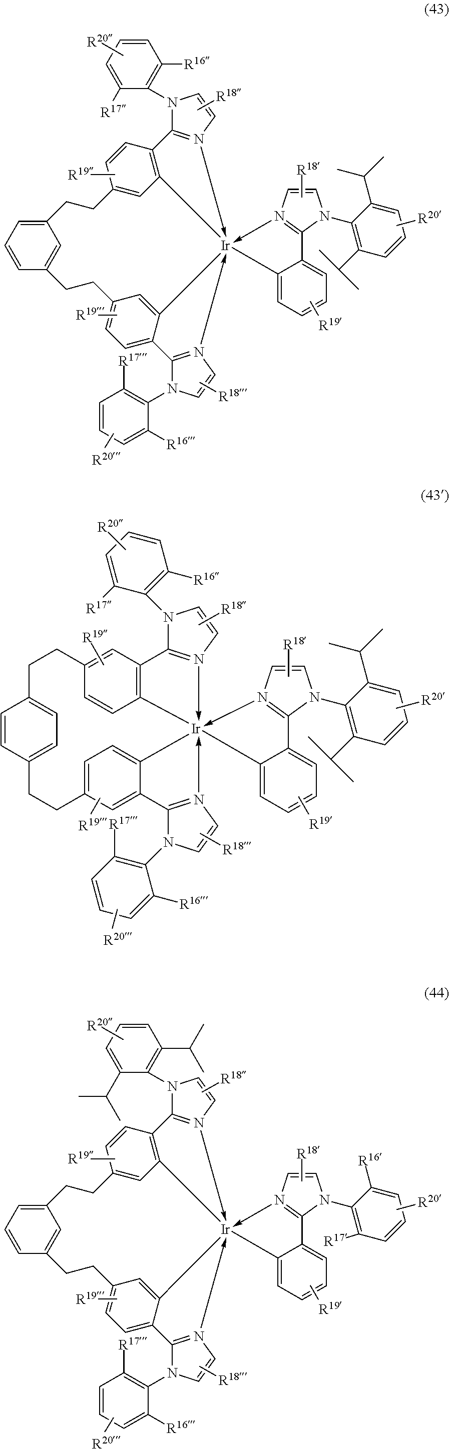

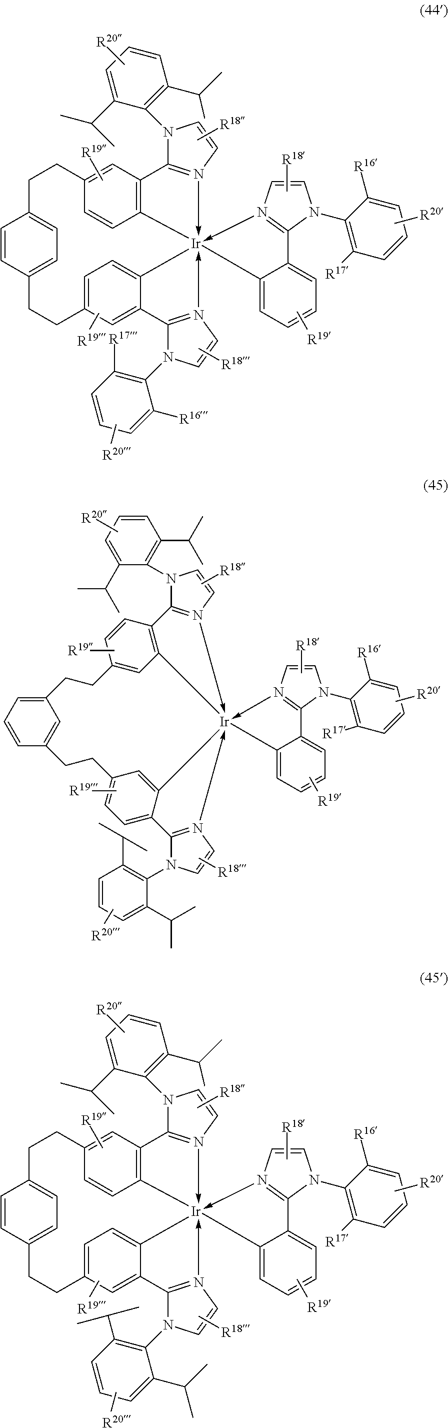

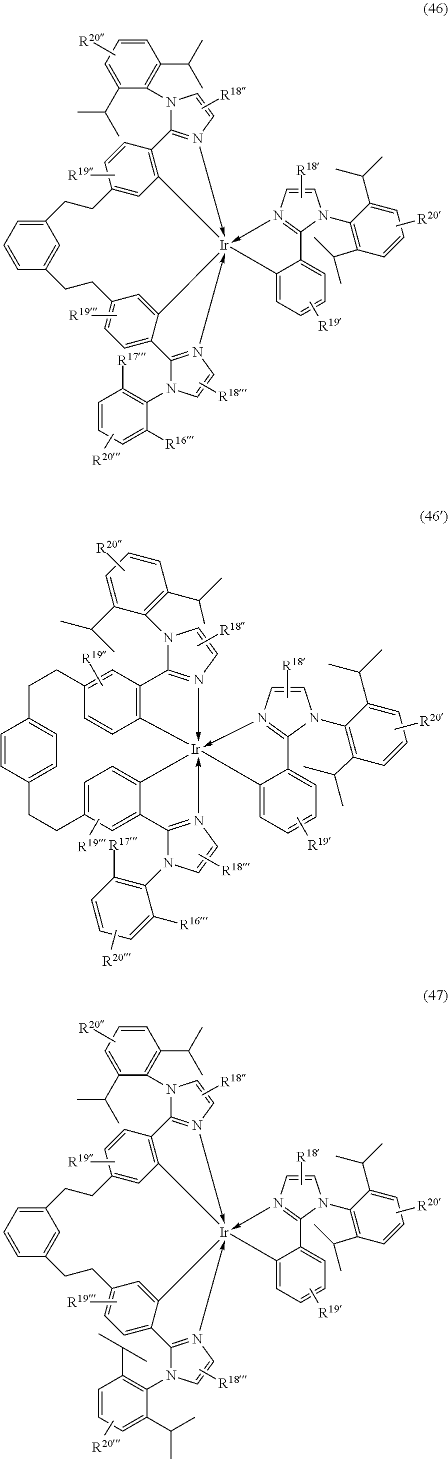

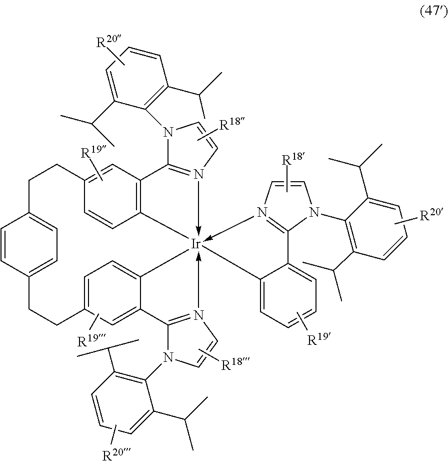

In the same way, provided the right selection of the bidentate ligand units L¹ and L² and of the additional bidentate ligand L′ has been made, green-emitting complexes are expected when at least one of these bidentate ligands L¹, L² and L′ is selected from formula (31) and orange/red emitting complexes from bidentate ligands selected from formulae (32) and (33).

Because of expected reduced ligand scrambling when starting from a tetradentate ligand wherein two ligands units L¹ and L² are linked to one another, the syntheses of heteroleptic complexes (L¹≠L²≠L′) in accordance with the present invention are believed to lead to easier purification process and higher yield than synthesis starting from bidentate L¹, L² and L′ ligands, which would be highly valuable. Heteroleptic complexes are indeed of particular interest because their photophysical, thermal and electronic properties as well as their solubility can be tuned by selecting appropriate combination of ligands. Furthermore, they have been observed in some cases (e.g. US2010/0141127A1) to yield better device lifetimes in OLEDs.

Given the very broad variety of bidentate ligand unit L¹ and L² and of additional ligand L′ which could be selected in the complexes involving asymmetric tetradentate ligands in accordance with the present invention, light-emitting materials combining high solubility in most organic solvents and desired emission properties, particularly in the blue region, are made available which is quite advantageous for low cost OLEDs production. It is indeed possible to properly select at least one of the bidentate ligand units L¹ to L² or the additional bidentate ligand L′ in order to impart higher solubility to the light-emitting complexes without changing its emission wavelength.

Another object of the invention is the use of the light emitting transition metal complexes as above described in the emitting layer of an organic light emitting device, e.g. a light emitting electrochemical cell (LEEC) or an organic light emitting diode (OLED).

In particular, the present invention is directed to the use of the light emitting transition metal complexes as above described as dopant in a host layer, functioning as an emissive layer in an organic light emitting device.

Should the light emitting transition metal complexes be used as dopant in a host layer, they are generally used in an amount of at least 1% wt, preferably of at least 3% wt, more preferably of least 5% wt with respect to the total weight of the host and the dopant and generally of at most 35% wt, preferably at most 25% wt, more preferably at most 15% wt.

The present invention is also directed to an organic light emitting device, in particular an organic light emitting diode (OLED) comprising an emissive layer (EML), said emissive layer comprising the light emitting transition metal complexes or mixture of same as above described, optionally with a host material (wherein the light emitting transition metal complexes as above described are preferably present as a dopant), said host material being notably suitable in an EML in an OLED.

The present invention is also directed to light emitting electrochemical cells (LEEC) containing ionic complexes in accordance with the present invention.

An OLED generally comprises:

a substrate, for example (but not limited to) glass, plastic, metal;
an anode, generally transparent anode, such as an indium-tin oxide (ITO) anode;
a hole injection layer (HIL) for example (but not limited to) PEDOT/PSS;
a hole transporting layer (HTL);
an emissive layer (EML);
an electron transporting layer (ETL);
an electron injection layer (EIL) such as LiF, Cs₂CO₃
a cathode, generally a metallic cathode, such as an Al layer.

For a hole conducting emissive layer, one may have a hole blocking layer (HBL) that can also act as an exciton blocking layer between the emissive layer and the electron transporting layer. For an electron conducting emissive layer, one may have an electron blocking layer (EBL) that can also act as an exciton blocking layer between the emissive layer and the hole transporting layer. The emissive layer may be equal to the hole transporting layer (in which case the exciton blocking layer is near or at the anode) or to the electron transporting layer (in which case the exciton blocking layer is near or at the cathode).

The emissive layer may be formed with a host material in which the light emitting material or mixture of these materials as above described resides as a guest or the emissive layer may consist essentially of the light emitting material or mixture of these materials as above described itself. In the former case, the host material may e.g. be a hole-transporting material selected from the group of substituted tri-aryl amines. Preferably, the emissive layer is formed with a host material in which the light emitting material resides as a guest. The host material may be an electron-transporting material e.g. selected from the group of oxadiazoles, triazoles and ketones (e.g. Spirobifluoreneketones SBFK) or a hole transporting material. Examples of host materials are 4,4′-N,N′-dicarbazole-biphenyl [“CBP”] or 3,3′-N,N′-dicarbazole-biphenyl [“mCBP”] which have the formula:

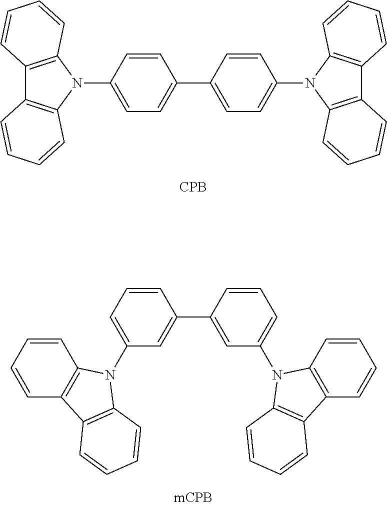 [SMILES: c1ccc2c(c1)c1ccccc1n2-c1ccc(-c2ccc(-n3c4ccccc4c4ccccc43)cc2)cc1 ; "CPB" ; c1cc(-c2cccc(-n3c4ccccc4c4ccccc43)c2)cc(-n2c3ccccc3c3ccccc32)c1]

Optionally, the emissive layer may also contain a polarization molecule, present as a dopant in said host material and having a dipole moment, that generally affects the wavelength of light emitted when said light emitting material as above described, used as dopant, luminesces.

A layer formed of an electron transporting material is advantageously used to transport electrons into the emissive layer comprising the light emitting transition metal complex and the (optional) host material. The electron transporting material may be an electron-transporting matrix selected from the group of metal quinoxolates (e.g. Alq₃, Liq), oxadiazoles, triazoles and ketones (e.g. Spirobifluorene ketones SBFK). Examples of electron transporting materials are tris-(8-hydroxyquinoline)aluminum of formula [“Alq₃”] and spirobifluoreneketone SBFK:

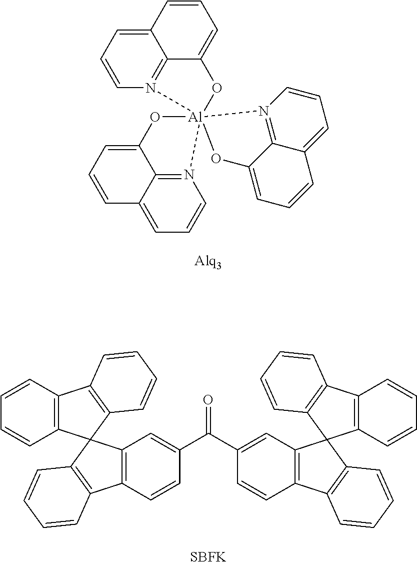

A layer formed of a hole transporting material is advantageously used to transport holes into the emissive layer comprising the light emitting material as above described and the (optional) host material. An example of a hole transporting material is 4,4′-bis[N-(1-naphthyl)-N-phenylamino]biphenyl [“α-NPD”].

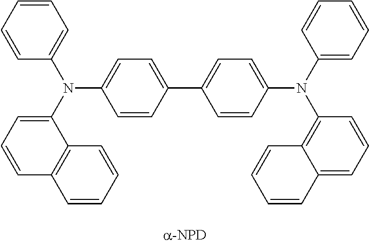 [SMILES: c1ccc(N(c2ccc(-c3ccc(N(c4ccccc4)c4cccc5ccccc45)cc3)cc2)c2cccc3ccccc23)cc1]

The use of an exciton blocking layer (“barrier layer”) to confine excitons within the luminescent layer (“luminescent zone”) is usually preferred. For a hole-transporting host, the blocking layer may be placed between the emissive layer and the electron transport layer. An example of a material for such a barrier layer is 2,9-dimethyl-4,7-diphenyl-1,10-phenanthroline (also called bathocuproine or “BCP”), which has the formula

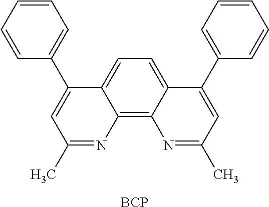 [SMILES: Cc1cc(-c2ccccc2)c2ccc3c(-c4ccccc4)cc(C)nc3c2n1 ; "BCP"]

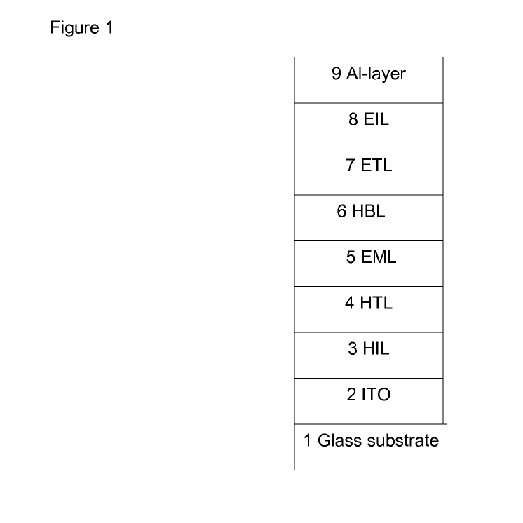

The OLED has preferably a multilayer structure, as depicted in FIG. 1, wherein 1 is a glass substrate, 2 is an ITO layer, 3 is a HIL layer comprising e.g. PEDOT/PSS, 4 is a HTL layer comprising e.g. α-NPD, 5 is an EML comprising e.g. mCBP as host material and the light emitting material or mixture of these materials as above defined as dopant in an amount of about 15% wt with respect to the total weight of host plus dopant; 6 is a HBL comprising e.g. BCP; 7 is an ETL comprising e.g. Alga; 8 is an EIL comprising e.g. LiF and 9 is an Al layer cathode

The asymmetric tetradentate ligands forming part of the subunit of the light emitting transition metal complexes in accordance with the present invention may be obtained by a number of processes which have been principally described in the literature and are known to the skilled person.

By way of example a stepwise Sonogashira coupling reaction may be mentioned here.

The Sonogashira coupling reaction is a cross coupling reaction used widely in organic synthesis to form carbon-carbon bonds between a terminal alkyne group and an aryl or vinyl halide using a palladium based catalyst. The reaction has the advantage that it can be carried out under mild conditions, e.g. at room temperature and/or in aqueous media and with mild bases which is advantageous to avoid or suppress side reactions which may occur otherwise.

In principle the starting materials of the reaction may be a compound A-(B¹)-L¹ with a terminal ethynyl group which is reacted with a compound L² bearing a halide group or starting with a compound A-(B¹)-L¹ with a halide group which is reacted with a compound L² bearing a terminal ethynyl group. Respective starting materials may be obtained in accordance with methods known to the skilled person or are available commercially form certain suppliers.

Another possibility to obtain the asymmetric tetradentate ligands present in the complexes of the present invention is the so called Suzuki-Myaura coupling, according to which phenylboronic acid treacts with haloarenes. The reaction proceeds smoothly in the presence of bases with good yields. The principle reaction scheme for coupling two phenyl units may be depicted as follows:

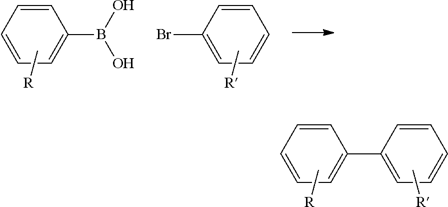

The reaction proceeds smoothly and under mild conditions with palladium compounds, e.g. tetrakis (triphenylphosphine)palladium, Pd(PPh3)4, as catalyst in the presence of bases like sodium hydroxide or sodium carbonate as bases. In some cases weak bases like sodium carbonate have proved to be advantageous over strong bases like NaOH.

Instead of the bromides, the respective iodides are also suitable reactants whereas the respective chlorides are usually inert under the reaction conditions.

Furthermore, the phenyl group in the above reaction scheme may be substituted or unsubstituted and the phenyl ring may be replaced by other aromatic or heteroaromatic ring systems to obtain a wide variety of compounds.

It is easily recognizable that subsequent repetition of this reaction can provide the desired asymmetric tetradentate ligands.

Further details concerning the Suzuki-Myaura coupling and suitable reaction conditions can be taken from Suzuki et al., Synth. Comm. 11(7), 513-519 (1981).

Still another possibility to obtain the asymmetric tetradentate ligands may be the arylation of primary or secondary amines with e.g. biphenyl compounds according to the following principal reaction scheme

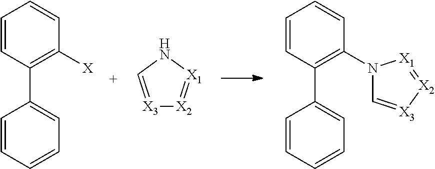

Similar to the Suzuki-Myura coupling the reaction can be repeatedly applied to obtain the desired compounds. Further details concerning reaction conditions can be taken from Angew. Chem. Int. Ed. 42, 2051-2053 (2003) to which reference is made in this regard. Similar to the Suzuki-Myaura coupling this reaction is a versatile tool and can be applied to a broad range of starting materials.

It is also possible to combine the two aforementioned reactions in two subsequent steps to obtain desired tetradentate ligands. This may be generally depicted as follows:

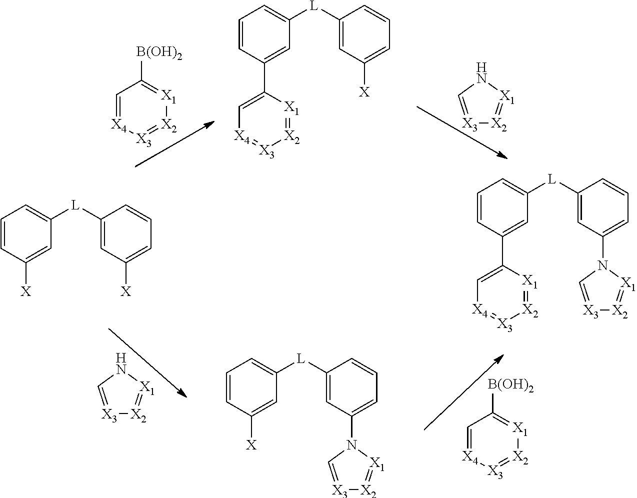

The skilled person will easily recognize that the upper route uses the Suzuki-Myaura coupling first followed by the amine arylation whereas the lower route uses the amine arylation first followed by a Suzuki-Myaura coupling.

In the above general reaction scheme, the aryl rings may carry substituents or may be unsubstituted.

The reaction conditions will be selected by the skilled person based on his professional knowledge and the information available for reactions of this type.

The light emitting transition metal complexes comprising asymmetric tetradentate ligands in accordance with the present invention may be prepared using known methods described in the prior art.

A first preferred process to synthesize the light emitting transition metal complexes in accordance with the present invention which comprise an asymmetric tetradentate ligand and an additional bidentate ligand L′ comprises reacting the halo-bridged dimer complex of general formula [L′₂M(μ-X)₂ML′₂] comprising the additional bidendate ligand L′ and bridging halide ligand X⁻ with the desired asymmetric tetradentate ligand in a solvent mixture of an organic solvent and water comprising more than 25 vol % of water, based on the volume of the overall solvent mixture, at a temperature of from 50 to 260° C., optionally in the presence of from 0 to 5 molar equivalents, relative to the number of moles of halide X⁻ ion introduced into the reaction mixture through the halo-bridged dimer, of a scavenger for halide X⁻ ion and of from 0 to 10 vol %, based on the total volume of the solvent mixture, of a solubilisation agent increasing the solubility of the halo-bridged dimer in the reaction mixture.

The halo-bridged dimer complex of general formula [L′₂M(μ-X)₂ML′₂] which comprises the additional bidentate ligand L′ can be obtained according to known processes described in the literature, e.g. by reaction of the respective metal halides and/or their hydrates with additional bidentate ligand L′. Most preferred halides are chlorides and bromides. For example, in the case of iridium metal, a well-known procedure to synthesize the chloro-bridged dimer [L′₂Ir(μ-Cl)₂IrL′₂] consists to react IrCl₃.xH₂O with a slight excess of the bidentate ligand L′ (2.5 to 3 mol/mol Ir) in a 3:1 (v/v) mixture of 2-ethoxyethanol and water at reflux for ≈20 h.

In accordance with this preferred process, the reaction of the halo bridged dimer [L′₂M(μ-X)₂ML′₂] with the desired tetradentate ligand is carried out in a mixture of an organic solvent and water, which mixture comprises more than 25 vol % of water. The mixture preferably contains not more than 70 vol. % of an organic solvent and at least 30 vol. % of water.

According to this preferred process, the reaction is carried out in a solvent mixture comprising an organic solvent and water, preferably in a homogeneous solution. The term “homogeneous solution” used herein relates to the solvent mixture. Preferably, the organic solvent may be at least one selected from a group consisting of C₁˜C₂₀ alcohols, for example, methanol, ethanol, n-propanol, isopropanol, n-butanol, isobutanol or tert-butanol, oxanes, for example, dioxane or trioxane, C₁˜C₂₀ alkoxyalkyl ethers, for example, bis(2-methoxyethyl) ether, C₁˜C₂₀ dialkyl ethers, for example, dimethyl ether, C₁˜C₂₀ alkoxy alcohols, for example, methoxyethanol or ethoxyethanol, diols or polyalcohols, for example, ethylene glycol, propylene glycol, triethylene glycol or glycerol, polyethylene glycol, or dimethyl sulfoxide (DMSO), N-methyl pyrrolidone (NMP) or dimethyl formamide (DMF), and combinations thereof. More preferably, the organic solvent may be at least one selected from a group consisting of dioxane, trioxane, bis(2-methoxyethyl) ether, 2-ethoxyethanol and combinations thereof. Most preferably, the organic solvent is dioxane or bis(2-methoxyethyl) ether (hereinafter referred to as diglyme)

The reaction temperature is generally in the range of from 50 to 260° C., preferably in the range of from 80 to 150° C. In some specific embodiments, the process is carried out at a pressure of from 1×10³ to 1×10⁸ Pa, preferably 1×10⁴ to 1×10⁷ Pa, and most preferably 1×10⁵ to 1×10⁶ Pa.

The tetradentate asymmetric ligand is preferably used in a stoichiometric amount relative to the amount of metal in the halo-bridged dimer or in a molar excess relative to the amount of metal in the halo-bridged dimer. In a more specific embodiment, the ligand compound is used in an amount of 10 to 3000 mol percent excess, preferably 50 to 1000 mol percent excess, most preferably 100 to 800 mol percent excess.

This process can be carried out in the presence or in the absence of a scavenger for halide ion X⁻. If halide ion scavenger is present, it is used in amount of up to 5, preferably up to 3 moles per mole of halide X⁻ ion introduced into the reaction mixture through the halo-bridged dimer. Preferred scavengers are silver salts. Most preferred silver salts are tetrafluoroborate, trifluoroacetate or triflate.

In certain cases, where the solubility of the halo-bridged dimer in the solvent mixture is very low, it has proven to be advantageous to add up to 10 vol %, preferably of from 0.1 to 10 vol %, even more preferably of from 0.5 to 5 vol %, based on the volume of the solvent mixture, of a solubilising agent to improve the solubility of the dimer in the reaction solvent. DMSO has shown to work particularly well as solubilizing agent in certain cases.

Given that proton ions, H₃O⁺, produced during the reaction may have an inhibitory effect, a neutralization step could be preferably carried out during the reaction in order to improve the complex yields.

In one embodiment of this process the halo-bridged dimer complex of general formula [L′₂M(μ-X)₂ML′₂] comprising the additional bidentate ligand L′ can be treated in a 1^{st} step with a scavenger for halide ion (most preferred scavenger being silver salt, silver triflate e.g.) in an organic solvent, e.g. a CH₂Cl₂/MeOH mixture or ethanol and the intermediate complex obtained after filtration and removal of solvents can be reacted in a 2^{nd} step with the desired asymmetric tetradentate ligand at a temperature of from 50 to 260° C. in a solvent mixture of an organic solvent and water comprising more than 25 vol % of water.

In another embodiment of this process, the precursor complex obtained by reaction of the desired tetradentate asymmetric ligand with metal halides and/or their hydrates, which could be considered as a halo-bridged dimer complex, can be reacted with the desired additional bidentate ligand L′ in a solvent mixture of an organic solvent and water comprising more than 25 vol % of water, based on the volume of the overall solvent mixture, at a temperature of from 50 to 260° C., optionally in the presence of from 0 to 5 molar equivalents, relative to the number of moles of halide X⁻ ion introduced into the reaction mixture through the halo-bridged dimer, of a scavenger for halide X⁻ ion and of from 0 to 10 vol %, based on the total volume of the solvent mixture, of a solubilisation agent increasing the solubility of the halo-bridged dimer in the reaction mixture. For example, this precursor complex in the case of iridium metal could be obtained by reacting IrCl₃.xH₂O with a stoichiometric or a slight excess amount of the desired tetradentate ligand (1.0 to 3.0 mol/mol Ir) in a 3:1 (v/v) mixture of 2-ethoxyethanol and water at reflux for ≈20 h.

The precursor complex obtained by reaction of the desired tetradentate asymmetric ligand with the selected metal halides could also be used as starting material in other synthesis routes to the light-emitting transition metal complexes in accordance with this invention.

Such precursor could e.g. be treated directly with the bidentate additional ligand L′ in an organic solvent at a temperature in the range of from 40° C. to 260° C.

Alternatively the same precursor can be treated in a first step with a scavenger for halide ions in an organic solvent, e.g a methanol/dichloromethane mixture, ethanol or acetone, and the intermediate complex obtained after filtration and removal of the solvent can then be treated in a second step with the additional bidentate ligand L′ in an organic solvent at a temperature in the range of from 40° C. to 260° C.

A one-pot variant of this synthesis can also be used. In that case the precursor is reacted with the additional bidentate ligand L′ in presence of a scavenger for halide ion in an organic solvent at a temperature in the range of from 40° C. to 260° C.

The reaction with the additional bidentate ligand L′ in these three last cases could be performed in presence of an organic or inorganic base in order to increase the yield.

Preferably, the organic solvent used to perform the reaction with the additional bidentate ligand L′ in these three last synthesis routes may be at least one selected from a group consisting of chlorinated solvents, for example CH₂Cl₂, C₁˜C₂₀ alcohols, for example, methanol, ethanol, n-propanol, isopropanol, n-butanol, isobutanol or tert-butanol, oxanes, for example, dioxane or trioxane, C₁˜C₂₀ alkoxyalkyl ethers, for example, bis(2-methoxyethyl) ether, C₁˜C₂₀ dialkyl ethers, for example, dimethyl ether, C₁˜C₂₀ alkoxy alcohols, for example, methoxyethanol or ethoxyethanol, diols or polyalcohols, for example, ethylene glycol, propylene glycol, triethylene glycol or glycerol, polyethylene glycol, C₁˜C₂₀ ketones, for example acetone, butanone, or dimethyl sulfoxide (DMSO), N-methyl pyrrolidone (NMP), acetonitrile or dimethyl formamide (DMF), and combinations thereof.

A three-step synthesis analogous to that described in JP2008/303150 for the synthesis of homoleptic complexes comprising 2-phenylimidazole type ligands which starts from IrCl₃ and passes successively by the chloro-bridged dimer and the heteroleptic acac complex to finally obtain the tris homoleptic complexes could also be used. In this case, the dimer precursor obtained from the reaction of the desired tetradentate asymmetric ligand with the selected metal halides (MX₃.xH₂O) could be reacted with acetylacetonate type ligands in presence of a base (e.g. Na₂CO₃) in an organic solvent, e.g. 2-ethoxyethanol, to lead to a heteroleptic complex comprising the asymmetric tetradentate ligand as the main ligand and acetylacetonate as ancillary bidentate ligand. In a last step the heteroleptic complex comprising the acetylacetonate as ancillary can then be reacted with an additional bidentate ligand L′ to give the heteroleptic complexes comprising the desired asymmetric tetradentate ligand and the desired additional bidentate ligand L′.

Metal acetylacetonate complexes (e.g. (Ir(acac)₃) could also be used as starting materials. It has been shown that light emitting transition metal complexes comprising asymmetric tetradentate ligands in accordance with the present invention could be obtained e.g by treating Ir(acac)₃) with a mixture of the desired tetradentate asymmetric ligand and the selected additional bidentate ligand L′ at high temperatures (e.g. >200° C.) without any added solvent.

When the additional bidentate L′ ligand corresponds to a ĈC ligand which is bound to the metal via a neutral donor atom which is a carbon in the form of a carbene and through a carbon atom having formally a negative charge, a carbene precursor complex involving the additional bidentate ligand L′ could be first prepared which can then be allowed to react in a second step with the tetradentate ligand in presence of a silver salt. In the case of iridium e.g, this carbene precursor can be an iridium (I) complex e.g. [Ir(COD)(L′)Cl] wherein COD corresponds to a 1,5-cyclooctadiene ligand and wherein L′ is linked to the iridium (I) ion via its carbene part.

The light-emitting transition metal complexes in accordance with the present invention may be purified by recrystallization, column chromatography or sublimation to name only a few possibilities

The skilled person will use his professional knowledge to select the suitable reactants and reaction conditions based on the specific combination of tetradentate and bidentate or monodentate ligands.

Other synthesis methods are suitable and are known to the skilled person so that no further details are necessary here.

The light emitting transition metal complexes in accordance with the present invention provide the possibility to precisely adjust and modify the properties by selection of the bidentate ligand units L¹ and L² and of the additional bidentate ligand L′ in accordance with the specific application case.

Thereby the emission properties of organic electronic devices comprising the light emitting materials in accordance with the present invention can be finely tuned and adjusted to the specific application.

### EXAMPLES

1°) Synthesis of complexes wherein L¹≠L²≠L′ and wherein both the bidentate ligand units L¹ and L² of the asymmetric tetradentate ligand as well as the additional bidentate ligand L′ are cyclometallated ĈN ligands bound to the iridium metal via a neutral donor nitrogen atom and through a carbon atom having formally a negative charge

### Example 1

Synthesis of complex I (formula below) wherein one bidentate ligand unit, e.g. L¹ of the asymmetric tetradentate ligand pertains to general formula (10) and the other bidentate ligand unit L² of the asymmetric tetradentate pertains to general formula (8) while the additional bidentate ligand L′ pertains to general formula (8). More specifically the asymmetric tetradentate ligand corresponds to ligand L48 (as defined hereinafter) wherein the bidentate ligand unit L¹ pertains to general formula (31) and the bidentate ligand unit L² pertains to general formula (8) while the additional bidentate ligand L′ pertain to general formula (11) and more particularly to formula (17).

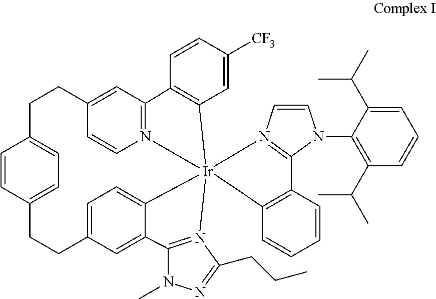

### a) Synthesis of Asymmetric Tetradentate Ligand L48

The bidentate ligand unit L¹ pertains to general formula (31) and the bidentate ligand unit L² pertains to general formula (8); the central scaffold A is a phenyl ring and both pending arms B¹ and B² are —CH₂—CH₂— units linked in para position to each other on the A phenyl ring.

Ligand L48 was synthesized according to the following scheme:

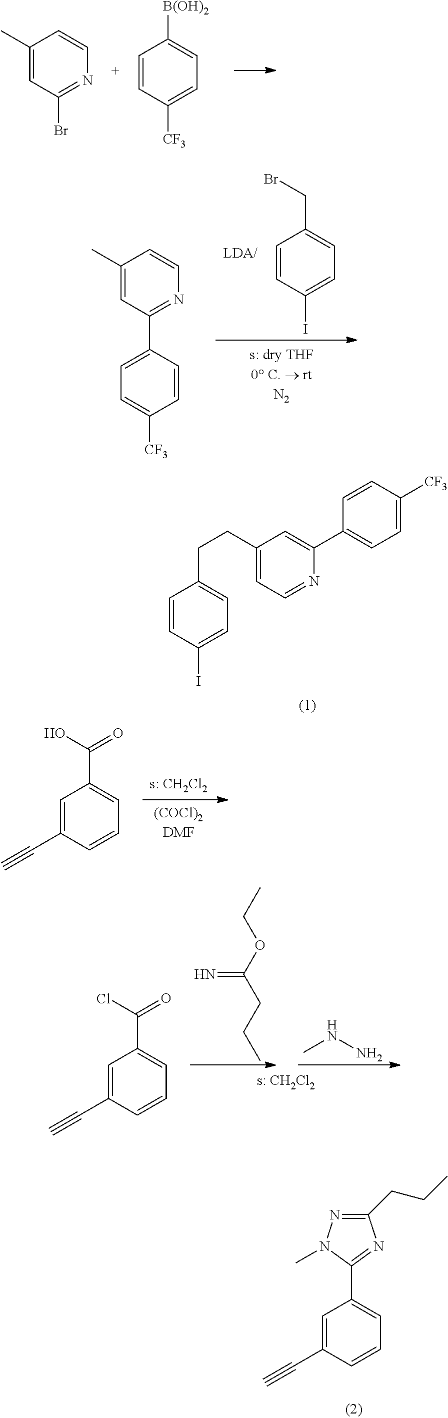

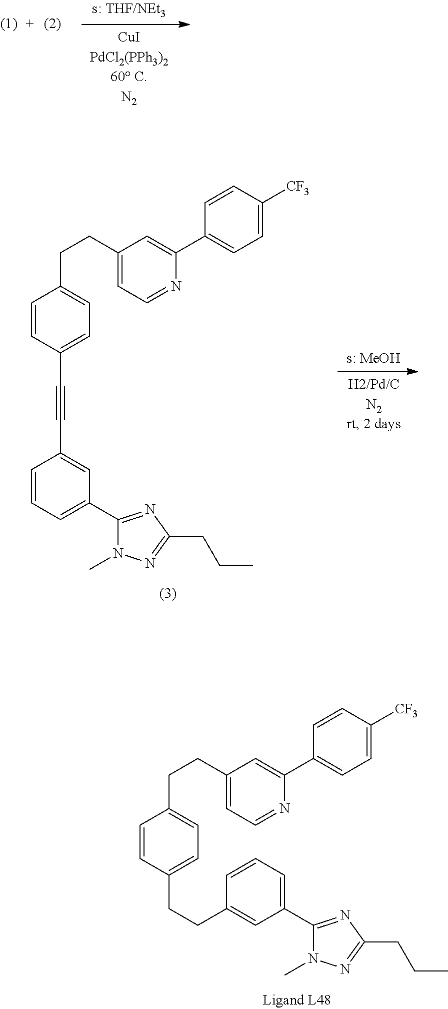 [SMILES: CCCc1nc(-c2cccc(C#Cc3ccc(CCc4ccnc(-c5ccc(C(F)(F)F)cc5)c4)cc3)c2)n(C)n1 ; CCCc1nc(-c2cccc(CCc3ccc(CCc4ccnc(-c5ccc(C(F)(F)F)cc5)c4)cc3)c2)n(C)n1]

### Synthesis of 4-(4-iodophenethyl)-2-(4-(trifluoromethyl)phenyl)pyridine intermediate (1)

1st step: A two-neck flask was filled with 120 mL of THF and 20 mL of a 2 M K₂CO₃ solution. Nitrogen was bubbled through the solvent mixture. 0.788 mL of 2-bromo-4-methylpyridine (7.1 mmol) and 1.62 g of 4-(trifluoromethyl)phenylboronic acid (8.5 mmol) were then added. After bubbling nitrogen for another ten minutes, 0.4 g of tetrakis(triphenylphosphino)palladium(0) (0.34 mmol) were added and the reaction mixture was refluxed under nitrogen overnight. After letting it cool down to room temperature, the mixture was extracted between CH₂Cl₂ and water. The combined organic phases were dried over MgSO₄ and filtered. The solvent was removed leading to a yellow oil. The crude product was purified by column chromatography (SiO₂; Hexane/Ethylacetate, 7:3) leading to 1.1 g of the desired product as a white solid, as confirmed by 1H-NMR and electrospray ionization mass spectrometry.

m/z (ESI-MS+) found 238.0840 ([M+H]⁺), 260.0655 ([M+Na]⁺).

2^{nd} step: 1.05 g (4.4 mmol) of 4-methyl-2-(4-(trifluoromethyl)phenyl)pyridine from 1st step were placed in a flame dried Schlenk flask. It was evacuated and refilled with nitrogen three times. Dry THF (15 mL) was added and the flask was placed in an ice bath. 2.95 mL (4.4 mmol) of a 1.5 M solution of lithium diisopropylamide were added dropwise. The solution was stirred at this temperature for 1.5 h. A solution of 1.31 g (4.4 mmol) of 4-iodobenzyl bromide in 10 mL THF was prepared in a second flask under nitrogen. It was then added dropwise to the first solution and the mixture was stirred at ambient temperature over night. Water was then added to quench the reaction. After extraction between ethylacetate and water the organic layer was dried over MgSO₄ and filtered. After removal of the solvent the crude compound was purified by column chromatography on SiO₂ with hexane/EtOAc 7:3 to get the desired product as a white solid, as confirmed by 1H-NMR and electrospray ionization mass spectrometry. Yield: 0.34 g

m/z (ESI-MS+) calcd 454.0274 ([M+H]⁺). found 454.0267.

¹H NMR (300 MHz, CDCl₃) δ 8.55 (s, 1H), 7.97 (s, 2H), 7.69 (s, 2H), 7.55 (d, J=8.3 Hz, 2H), 7.39 (s, 1H), 7.05 (s, 1H), 6.84 (d, J=8.2 Hz, 2H), 2.88 (d, J=3.8 Hz, 4H).

### Synthesis of 5-(3-ethynylphenyl)-1-methyl-3-propyl-1H-1,2,4-triazole intermediate (2)

2.23 g (15.3 mmol) of 3-ethynylbenzoic acid were suspended in 50 mL of dichloromethane. 5.2 mL (61 mmol) of oxalyl chloride were added followed by the addition of 3 drops of dry DMF. The reaction mixture was stirred at room temperature until all solids had dissolved, indicating complete conversion to the acid chloride. The solvent and excess oxalyl chloride were removed in vacuo and the resulting solid used immediately without further purification.

It was redissolved in 50 mL of CH₂Cl₂ and 2.31 g (15.3 mmol) of ethylbutyrimidate hydrochloride were added. A solution of 4.22 mL (30.5 mmol) of triethylamine in 10 mL of CH₂Cl₂ was added dropwise and the resulting mixture was stirred at room temperature over night. The solution was washed with water (3×50 mL). After drying over MgSO₄ the mixture was filtered into a round bottom flask.

0.8 mL (15.3 mmol) of methylhydrazine were added and the reaction mixture was stirred at room temperature over night. The next day it was again washed with water, dried over MgSO₄ and filtered. The solvent was removed under vacuum to yield the crude product as a yellow oil. It was purified by column chromatography on SiO₂ with Hex/EtOAc 7:3 yielding a white solid in 70% yield as confirmed by 1H-NMR and electrospray ionization mass spectrometry.

¹H NMR (300 MHz, CDCl₃) δ 7.75-7.68 (m, 1H), 7.62-7.55 (m, 1H), 7.52 (dt, J=7.7, 1.3 Hz, 1H), 7.39 (t, J=7.8 Hz, 1H), 3.86 (s, 3H), 3.07 (s, 1H), 2.79-2.52 (m, 2H), 1.74 (dd, J=15.1, 7.5 Hz, 2H), 0.94 (t, J=7.4 Hz, 3H).

m/z (ESI-MS+) calcd. 226.1339 ([M+H]⁺). found 226.1342.

### Synthesis of 4-(4-((3-(1-methyl-3-propyl-1H-1,2,4-triazol-5-yl)phenyl)ethynyl)phenethyl)-2-(4-(trifluoromethyl)phenyl)pyridine (3)

A round bottom flask was charged with 0.67 g (3 mmol) of compound (2) and 1.34 g (3 mmol) of compound (1). A 1:1 mixture of NEt₃ and THF (30 mL) was used as a solvent. Nitrogen was bubbled through the solution for 10 min. 63 mg (0.09 mmol) of PdCl₂(PPh₃)₂ and 30 mg (0.15 mmol) of CuI were added and the reaction mixture was heated to 65° C. over night. After letting the solution cool down to room temperature the mixture was extracted between ethylacetate and water. The organic phase was dried over MgSO₄, filtered and the solvent removed. The crude compound was purified by column chromatography on SiO₂ with hexane/EtOAc 7:3 to get the desired product as a light yellow solid, as confirmed by 1H-NMR and electrospray ionization mass spectrometry. Yield: 0.64 g

¹H-NMR (CDCl₃): δ=8.45 (d, 1H), 7.90 (d, 2H), 7.69 (s, 1H), 7.59 (d, 2H), 7.50 (d, 2H), 7.34 (m, 4H), 6.95 (m, 3H), 3.81 (s, 3H), 2.88 (s, 3H), 2.56 (t, 2H), 1.66 (m, 2H), 0.83 (t, 4H);

m/z (ESI-MS+) calcd 551.2417 ([M+H]⁺). found 551.2411.

Synthesis of Asymmetric Tetradentate Ligand L48

0.4 g of compound (3) were placed in a thick-wall Schlenk flask. Methanol was added. It was degassed with three cycles of evacuation and refilling with nitrogen. A scoop of palladium on activated carbon (10 wt % loading) was added. The reaction mixture was degassed again three times. The flask was then set under a pressure of 1.5 bar of hydrogen gas and the mixture was stirred at ambient temperature for two days. Remained hydrogen was washed out with a stream of nitrogen. The black mixture was filtered through celite (diatomaceous earth) to get the pure product as a clear colorless oil in quantitative yield as confirmed by 1H-NMR and electrospray ionization mass spectrometry

¹H NMR (300 MHz, CDCl₃) δ 8.51 (d, J=4.9 Hz, 1H), 7.94 (t, J=16.8 Hz, 2H), 7.62 (d, J=8.2 Hz, 2H), 7.39 (t, J=8.0 Hz, 3H), 7.30 (t, J=7.5 Hz, 1H), 7.25-7.11 (m, 1H), 7.10-6.83 (m, 5H), 3.76 (s, 3H), 3.16-2.74 (m, 8H), 2.66 (dd, J=18.3, 10.8 Hz, 2H), 1.83-1.62 (m, 2H), 0.93 (t, J=7.4 Hz, 3H).

m/z (ESI-MS+) calcd. 555.2730 ([M+H]⁺). found 555.2729.

### b) Synthesis of Complex I Wherein the Additional Bidentate Ligand L′ Correspond to Formula (8) and More Specifically to Formula (17)

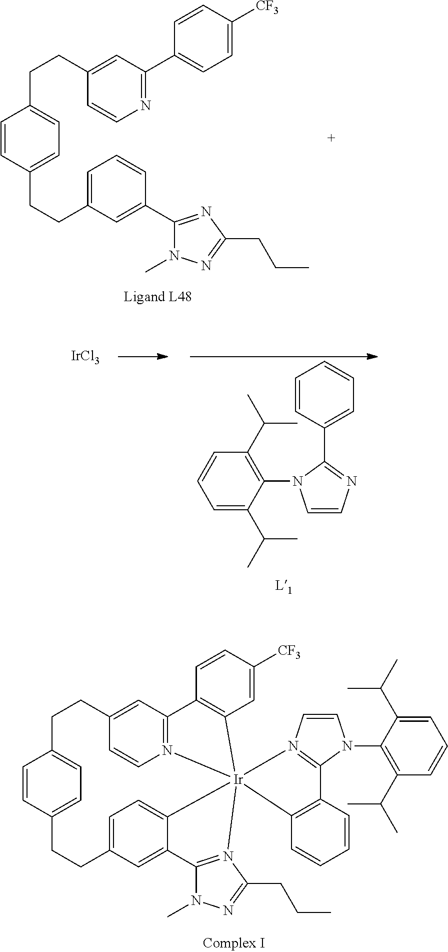

1.3 g (2.34 mmol) of ligand L48 and 0.81 g (2.34 mmol) of IrCl₃.xH₂O were heated to 120° C. in 2-ethoxyethanol under nitrogen over night. After cooling to room temperature, an excess of water was added to induce precipitation of the yellow product. It was filtered on a glass-frit and air-dried to get 1.37 g of a yellow powder. This powder was used without further purification.

0.1 g (0.064 mmol) of this dimer precursor and 78 mg (0.26 mmol) of 1-(2,6-diisopropylphenyl)-2-phenyl-1H-imidazole additional ligand L′1 were dissolved in ethylene glycol. Nitrogen was bubbled through the solution. 85 mg (0.38 mmol) of silver trifluoroacetate was added and the mixture was then heated in the dark to 190° C. over night. After cooling to room temperature, it was extracted between CH₂Cl₂ and water. The organic phase was dried over MgSO₄, filtered and the solvent removed. The crude product was purified twice by column chromatography on silica gel, using CH₂Cl₂/MeOH 5% leading to the desired complex as confirmed by ¹H-NMR and MALDI-TOF mass spectrometry.

λₘₐₓ of emission (nm) in CHCl₃ solution at room temperature: 525 (max), 551ₛₕ

2°) Synthesis of complexes wherein L¹≠L²≠L′ and wherein both the bidentate ligand units L¹ and L² of the asymmetric tetradentate ligand are cyclometallated ĈN ligands while the additional bidentate ligand L′ is a N̂N ligand which is bound to the iridium metal via a neutral donor nitrogen atom and through a nitrogen atom having formally a negative charge

### Example 2

Synthesis of complex II (formula hereafter) wherein one bidentate ligand unit, e.g. L¹ of the asymmetric tetradentate ligand pertains to general formula (10) and the other bidentate ligand unit L² of the asymmetric tetradentate pertains to general formula (8) while the additional bidentate N̂N ligand L′ pertains to general formula (9). More specifically the asymmetric tetradentate ligand corresponds to ligand L48 (from example 1) wherein the bidentate ligand unit L¹ pertains to general formula (31) and the bidentate ligand unit L² pertains to general formula (8) while the additional bidentate ligand L′ pertains to general formula (9) and more particularly to formula (29).

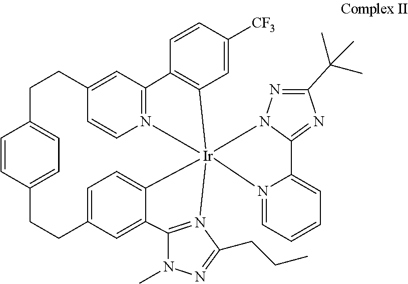

### Example 3

Synthesis of complex III (formula hereafter) wherein one bidentate ligand unit, e.g. L¹ of the asymmetric tetradentate ligand pertains to general formula (10) and the other bidentate ligand unit L² of the asymmetric tetradentate ligand pertains to general formula (8) while the additional bidentate N̂N ligand L′ pertains to general formula (9). More specifically the asymmetric tetradentate ligand corresponds to ligand L48 (from example 1) wherein the bidentate ligand unit L¹ pertains to general formula (31) and the bidentate ligand unit L² pertains to general formula (8) while the additional bidentate ligand L′ pertains to general formula (9) and more particularly to formula (30).

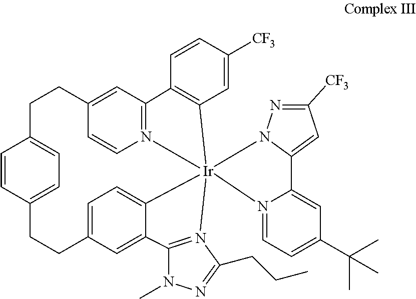

The same synthesis procedure has been used for complex II and complex III.

1^{st} Step: Dichloro-Bridged Dimer Precursor Synthesis from Tetradentate Ligand L48 and IrCl₃.xH₂O

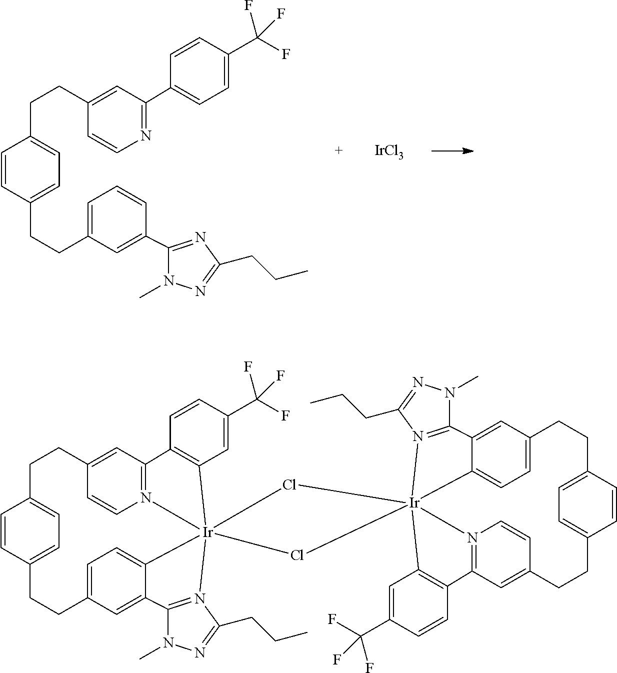

160 mL of a 2-ethoxyethanol/water 3:1 v/v mixture were placed in a 2-neck flask and nitrogen was bubbled through the solution. 0.2 g (0.36 mmol) of tetradentate ligand L48 was dissolved in 10 mL of hot 2-ethoxyethanol and added to the vigorously stirred solution. After additional 10 min of nitrogen bubbling, 0.13 g (0.36 mmol) of IrCl₃.xH₂O was added and the resulting mixture was heated to 120° C. over night. After cooling to room temperature, the mixture was poured into an excess of ice-cold water. The formed precipitate was filtered on a glass-frit and air-dried to get 0.19 g of a yellow powder. It was used for the next step without further purification.

2^{nd} Step: Reaction of the Dimer Precursor with Selected Additional Ligand L′

1 eq. of dimer precursor was dissolved in CH₂Cl₂ and treated with 2 eq. of silver trifluoromethanesulfonate. It was stirred at room temperature over night in the dark. After filtering through celite, 2.2 eq of the additional bidentate N̂N ligand L′ and 2.2 eq of triethylamine were added. The resulting mixture was heated to 50° C. over night. After filtering and removal of the solvent, the complexes were purified by column chromatography on silica gel, using CH₂Cl₂/MeOH as eluent (gradient of 1% to 5%).

Complex II: yield: 43 mg when starting from 280 mg of dimer-precursor.

¹H NMR (300 MHz CDCl₃) δ 8.75-5.51 (m, 17H), 4.37-3.60 (m, 2H), 3.35-2.31 (m, 5H), 2.0-0.28 (m, 20H),

MS-ESI: m/z: calcd. 947.3346 [M+H⁺]. found 947.3353.

λₘₐₓ emission (nm) in CH₂Cl₂ at room temperature=516

Complex III: yield: 16 mg when starting from 80 mg of dimer-precursor

¹H NMR (400 MHz CD₂Cl₂) δ 7.92-6.45 (m, 17H), 4.41-3.77 (m, 3H), 3.20-2.69 (m, 8H), 2.06-1.14 (m, 15H) 1.03 (dd, J=8.4, 6.5 Hz, 1H),

MS-MALDI: m/z: calcd. 1014.326 [M+H⁺]. found 1014.241.

λₘₐₓ emission (nm) in CH₂Cl₂ at room temperature: 502 (max), 527ₛₕ)

3°) Synthesis of complexes wherein L¹≠L²≠L′ and wherein both the bidentate ligand units L¹ and L² of the asymmetric tetradentate ligand are cyclometallated ĈN ligands while the additional bidentate ligand L′ is a ĈC ligand which means that it is bound to the iridium metal via a neutral donor atom which is a carbon in the form of a carbene and through a carbon atom having formally a negative charge.

### Example 4

Synthesis of complex IV (formula hereafter) wherein both the bidentate ligand units L¹ and L² of the asymmetric tetradentate ligand as well as the additional bidentate ĈC ligand L′ pertain to general formula (8). More specifically the asymmetric tetradentate ligand corresponds to ligand L49 (formula hereafter) wherein the bidentate ligand unit L¹ pertains to general formula (11) and more particularly to formula (16) and the bidentate ligand unit L² pertains to general formula (8) while the additional bidentate ĈC ligand L′ pertains to general formula (28).

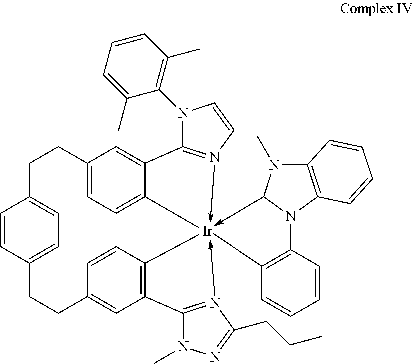

### a) Synthesis of Asymmetric Tetradentate Ligand L49

The bidentate ligand unit L¹ pertains to general formula (11) and more particularly to formula (16) and the bidentate ligand unit L² pertains to general formula (8); the central scaffold A is a phenyl ring and both pending arms B¹ and B² are —CH₂—CH₂— units linked in para position to each other on the A phenyl ring.

The ligand L49 was synthesized according to the following scheme:

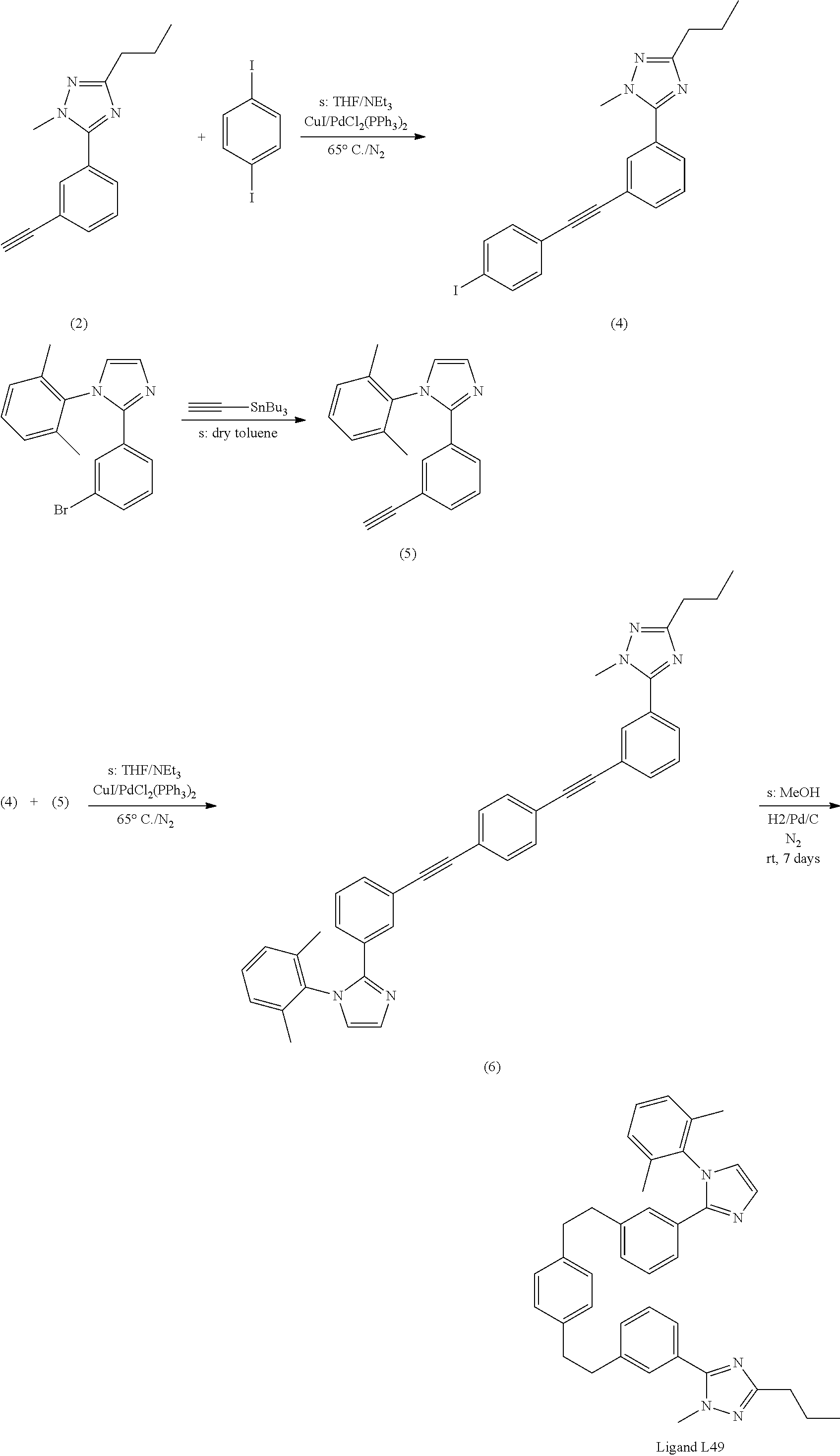

### Synthesis of 5-(3-((4-iodophenyl)ethynyl)phenyl)-1-methyl-3-propyl-1H-1,2,4-triazole intermediate (4)

2 g (8.9 mmol) of intermediate (2) from example 1 and 5.87 g (17.8 mmol) of 1,4-diiodobenzene were dissolved in 200 mL of a 1:1 mixture of THF and NEt₃. Nitrogen was bubbled through the solution for 10 min. 0.31 g (0.44 mmol) of PdCl₂(PPh₃)₂ was then added followed by addition of 0.17 g (0.89 mmol) of CuI. The reaction mixture was stirred at 65° C. over night. After cooling to room temperature, 100 mL of CH₂Cl₂ were added and it was washed with conc. NH₄OH three times to remove the copper catalyst. After two washings with water, the organic layer was dried over MgSO₄. After filtration and removal of the solvent, the crude mixture was purified by column chromatography on silica gel with hexane/ethyl acetate (Hex/EtOAc) 1:1 leading to 2.2 g of the desired product as confirmed by ¹H-NMR.

### Synthesis of 1-(2,6-dimethylphenyl)-2-(3-ethynylphenyl)-1H-imidazole intermediate (5)

5 g (15.3 mmol, 1 eq.) of 2-(3-bromophenyl)-1-(2,6-dimethylphenyl)-1H-imidazole were dissolved in dry toluene. 6.6 mL (22.9 mmol, 1.5 eq.) of tributyl(ethynyl)stannane were added and nitrogen was bubbled through the solution for 10 min. After the addition of 0.9 g (0.76 mmol, 0.05 eq) of tetrakis(triphenylphosphine)palladium(0) the bubbling was continued for another 10 min. The reaction mixture was heated to reflux over night. The solution was allowed to cool to room temperature and EtOAc and water were added. It was washed with water three times. The organic layers were dried over MgSO₄, filtered and the solvent removed. The product was purified by column chromatography on SiO₂ with Hex/EtOAc gradient (9:1 to 8:2 to 7:3) yielding a white solid. Yield: 1.75 g (42%).

### Synthesis of 5-(3-((4-((3-(1-(2,6-dimethylphenyl)-1H-imidazol-2-yl)phenyl)ethynyl)phenyl)ethynyl)phenyl)-1-methyl-3-propyl-1H-1,2,4-triazole intermediate (6)

2.1 g (4.9 mmol) of intermediate (4) and 1.34 g (4.9 mmol) of intermediate (5) were dissolved in 80 mL of a 1:1 mixture of THF and NEt₃. Nitrogen was bubbled through the solution for 10 min. 0.17 g (0.25 mmol) of PdCl₂(PPh₃)₂ was then added followed by the addition of 93 mg (0.49 mmol) of CuI. The reaction was stirred at 65° C. over night. After cooling to room temperature, 100 mL of CH₂Cl₂ were added and it was washed with conc. NH₄OH three times to remove the copper catalyst. After two washings with water, the organic layer was dried over MgSO₄. After filtration and removal of the solvent the crude mixture was purified by column chromatography on silica gel with Hex/EtOAc 1:1 leading to the desired product as confirmed by ¹H-NMR.

Synthesis of Asymmetric Tetradentate Ligand L49

The purified intermediate (6) was placed in a thick-wall Schlenk flask. Methanol was added. It was degassed with three cycles of evacuation and refilling with nitrogen. Palladium on activated carbon (10 wt % loading) was added. The reaction mixture was degassed again three times. The flask was then set under a pressure of 2 bar of hydrogen gas and the mixture was stirred at room temperature for seven days. The reaction mixture was then filtered through a pad of celite to remove the catalyst and the solvent was removed to obtain the expected ligand as a colorless oil. Yield: 1.6 g

¹H-NMR (400 MHz, CDCl₃): δ 7.56-7.28 (m, 7H), 7.23-6.88 (m, 10H), 3.89 (s, 3H), 3.11-2.70 (m, 10H), 2.07 (s, 6H), 1.88 (dd, 2H), 1.08 (t, 3H)

m/z (LCMS): calcd. 580.34 ([M+H⁺]). found, 580.53.

### b) Synthesis of the Additional Bidentate ĈC Ligand L′₄

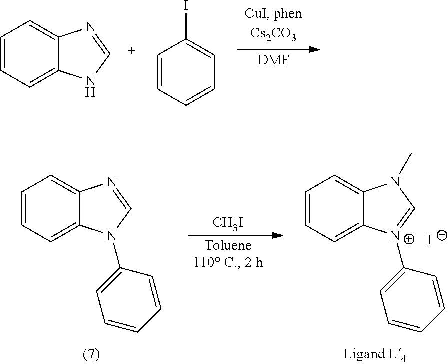

### Synthesis of 1-phenyl-1H-benzo[d]imidazole (7)

In an oven-dried two neck 250 mL round-bottom flask, CuI (646 mg; 3.4 mmol; 0.1 eq.), 1H-benzo[d]imidazole (4 g; 33.9 mmol; 1 eq.) and CsCO₃ (22.1 g; 67.8 mmol; 2 eq.) in anhydrous DMF (65 mL) were introduced. The reaction mixture was deoxygenated for 20 min by N₂ bubbling. Then, iodobenzene (8.3 g; 4.5 mL; 40.6 mmol; 1.2 eq.) and 1,10-phenanthroline (1.2 g; 6.8 mmol; 0.2 eq) were successively added. The resulting mixture was heated at 110° C. for 24 hours in the dark under inert atmosphere. After that reaction time, additional iodobenzene (3.6 g; 2 mL; 18 mmol; 0.5 eq.) was added, and the reaction was heated at 110° C. for one extra day. After this reaction time, the reaction mixture was cooled to room temperature and filtered. The filtered solids were washed with 120 mL of ethyl acetate. The filtrate was concentrated under vacuum. In order to remove the DMF, water (100 mL) was added to the residue and the aqueous phase was subsequently extracted with more ethyl acetate (3×30 mL). The combined organic layers were dried over MgSO₄ and the solvent removed using a rotary evaporator (rotavap). The residue was purified on column chromatography employing mixtures of hexane:ethyl acetate (2:1-0:1). The product was obtained as a yellow liquid. Yield: 4.8 g; 27.7 mmol; 73%.

¹H NMR (400 MHz, DMSO-d₆) δ 8.56 (s, 1H), 7.78 (dd, J=6.5, 2.4 Hz, 1H), 7.73-7.59 (m, 5H), 7.51 (dd, J=10.2, 4.3 Hz, 1H), 7.38-7.26 (m, 2H).

### Synthesis of 3-methyl-1-phenyl-1H-benzo[d]imidazol-3-ium ligand L′4

In a 50 mL round-bottom flask, 1-phenyl-1H-benzo[d]imidazole intermediate 7 (4.8 g; 25 mmol; 1 eq.) and CH₃I (8.8 g; 3.9 mL; 62 mmol; 2.5 eq.) were introduced in toluene (2 mL). The mixture was heated at 110° C. for 6 hours. After that time, a white precipitate appeared. The precipitate was then washed with THF (20 mL) and toluene (20 mL). The product was obtained as a white microcrystalline powder. Yield: 8.1 g; 24 mmol; 96%.

¹H NMR (400 MHz, CDCl₃) δ 11.05 (s, 1H), 7.85 (dd, J=18.2, 8.6 Hz, 3H), 7.76-7.55 (m, 6H), 4.47 (s, 3H).

### c) Preparation of (cyclooctadiene)(1-methyl-3-phenyl-2,3-dihydro-1H-benzoldlimidazol-2-yl)iridium(I) chloride [Ir(NHC)(COD)Cl] iridium carbene precursor complex

The synthesis was carried out according to a slightly modified procedure from the one reported in Dalton Trans. 2013, 42, 7318-7329.

Dry THF (120 mL) was added to a 2-neck round-bottom flask containing 3-methyl-1-phenyl-1H-benzo[d]imidazol-3-ium additional bidentate ligand L′4 (1.0 g; 3.0 mmol; 2 eq.), [Ir(COD)Cl]₂ (1.0 g; 1.5 mmol; 1 eq.) and NaN(SiMe₃)₂ (0.6 g; 3.0 mmol; 2 eq.) under nitrogen atmosphere. A color change from yellow to dark brown was observed. The reaction mixture was degassed by nitrogen bubbling for 20 minutes and allowed to stir for 3 h protected from light with aluminum foil. After this time, the solvent was removed in vacuo and the residue purified by column chromatography on silica employing mixtures of cyclohexane:DCM (2:1-1:1 v/v). The product was obtained as a bright yellow/green microcrystalline solid. Yield: 1.5 g; 2.76 mmol; 93%.

¹H NMR (400 MHz, CD₂Cl₂) δ 8.00 (d, J=7.1 Hz, 2H), 7.54 (dd, J=11.6, 7.3 Hz, 3H), 7.41 (d, J=7.9 Hz, 1H), 7.31 (dd, J=12.2, 7.8 Hz, 2H), 7.24 (d, J=8.1 Hz, 1H), 4.80 (m, 1H), 4.69 (m, 1H), 4.16 (s, 3H), 3.11 (m, 1H), 2.49 (m, 1H), 2.12 (m, 2H), 1.75 (m, 1H), 1.64 (m, 2H), 1.34 (m, 1H), 1.21 (m, 1H), 1.07 (m, 1H).

### d) Synthesis of Complex IV Wherein the Additional Bidentate ĈC Ligand L′ Correspond to General Formula (8) and More Specifically to General Formula (28)

In a 2-neck flask was placed 0.31 g (0.53 mmol) of asymmetric tetradentate ligand L49 in 350 mL of 2-ethoxyethanol. Argon was bubbled through the solution and it was covered in aluminum foil to protect the reaction mixture from light. 0.32 g (0.59 mmol) of the Ir carbene precursor complex from step (c) were added, followed by the addition of 93 mg (0.56 mmol) of silver acetate. The mixture was further degassed by bubbling argon for another 15 min and then heated to 70° C. for 1 h. It was then further heated to 150° C. over night. The solvent was removed and the crude product was purified by column chromatography on silica gel (DCM/MeOH 1% to 5%) leading to a mixture of isomers of the expected complex as a light yellow oil as confirmed by ¹H-NMR analysis and MALDI-TOF mass spectrometry. Yield: 53 mg.

1. A light-emitting transition metal complex comprising a transition metal M with an atomic number of at least 40 and a coordination number equal to six and a subunit with an asymmetric tetradentate ligand comprising two bidentate ligand units L¹ and L² and represented by general formula (1) 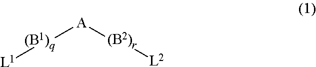
wherein q and r, independent of one another are 0 or 1, the pending arm units B¹, B², independent of one another are represented by general formula (2) 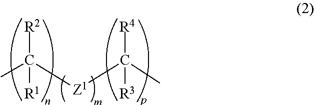
wherein Z¹ is a divalent group selected from the group consisting of —O—, —S—, —NR⁵—, —BR⁶—, —P(═O)R⁸—, —SiR⁹R¹⁰-, —N(R¹¹)—C(═O)—, —N═C(R¹²)—, —C(═O)—, —C═NR¹³—, —C(═S)— and —P(═S)(R¹⁴)—,
wherein R¹ to R¹⁴, which may be the same or different at each occurrence, are selected from hydrogen, halogen, NO₂, CN, NH₂, NHR′, N(R′)₂, B(OH)₂, B(OR′)₂, CHO, COOH, CONH₂, CON(R′)₂, CONHR′, SO₃H, C(═O)R′, P(═O)(R′)₂, S(═O)R′, S(═O)₂R′, P(R′)₃⁺, N(R′)₃⁺, OH, OR′, SR′ and alkyl, haloalkyl, aralkyl, aryl or heteroaryl groups with R′ being selected from hydrogen, alkyl, aralkyl, aryl and heteroaryl groups, and
n, m and p, independently of one another, are integers of from 0 to 8, the sum of n, m and p being at least 1 and
wherein at least one of the bidentate ligand units L¹ and L² is represented by formula (3) provided that L¹ and L² differ from each other 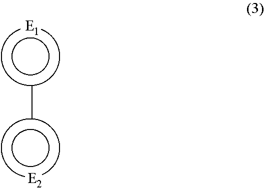
wherein
E₁ represents a nonmetallic atom group required to form a 5- or 6-membered heteroaromatic ring, optionally condensed with additional aromatic moieties or non aromatic cycles, said ring optionally having one or more substituents, optionally forming a condensed structure with the ring comprising E₂, and
E₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E₁, and
wherein the ring E₁ is bound to the transition metal via a neutral donor atom which is a carbon in the form of a carbene or a heteroatom and the ring E₂ is bound to the transition metal through a carbon atom having formally a negative charge or through a nitrogen atom having formally a negative charge and wherein central scaffold A is a bivalent linking group selected from compounds of general formulae (4) to (7) 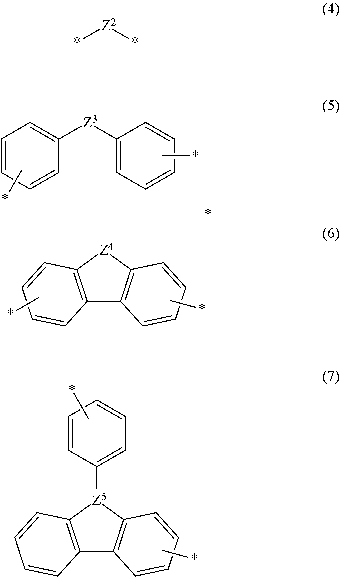
wherein
Z² is CR₂, NR, R₂⁺, RB, R₂B⁻, RP, RP(O), SiR₂, RAl, R₂Al⁻, RAs, RAs(O), RSb, RSb(O), RBi, RBi(O), O, S, Se or Te or a substituted or unsubstituted 5- or 6-membered carbocyclic, aromatic or heteroaromatic ring,
Z³ and Z⁴ are CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te,
Z⁵ is CR, N, R₂N⁺, B, RB⁻, P, P(O), SiR, Al, RAl⁻, As, As(O), Sb, Sb(O), Bi, Bi(O), and
R, which may be the same or different at each occurrence, is selected from the group consisting of hydrogen, alkyl, haloalkyl, aralkyl, aryl and heteroaryl.

2. The light-emitting transition metal complex in accordance with claim 1, wherein the transition metal M is selected from the group consisting of Re, Rh, Os, Ir or Ru.

3. The light-emitting transition metal complex in accordance with claim 1, wherein both of the bidentate ligand units L¹ and L² are represented by formula (3).

4. The light-emitting transition metal complex in accordance with claim 1, wherein Z², Z³ and Z⁴ are selected from the group consisting of CR₂, RN, O, S, RB, RP, RP(═O) and SiR₂, wherein Z⁵ is CR, N, B, P, P(O) or SiR.

5. The light-emitting transition metal complex in accordance with claim 1, wherein Z² is selected from the group consisting of substituted or unsubstituted 5- or 6-membered carbocyclic, aromatic or heteroaromatic rings.

6. The light-emitting transition metal complex in accordance with claim 1, wherein at least one of the bidentate ligands units L¹ and L² is represented by the formulae (8) to (10) 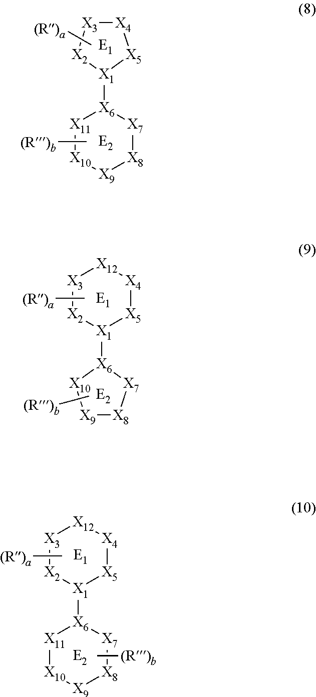
wherein
X₅ is a neutral donor atom via which the 5- or 6-membered aromatic or
heteroaromatic ring E₁ is bonded to the metal and which is a carbon in the form of a carbene or a heteroatom,
X₇ is a carbon atom having formally a negative charge or a nitrogen atom having formally a negative charge via which the 5- or 6-membered aromatic or heteroaromatic ring E₂ is bonded to the metal,
X₁, X₂, X₃, X₄, X₆, X₈, X₉, X₁₀, X₁₁, X₁₂ are independently from one other a carbon or a heteroatom, with the proviso that X₄ and X₁ are a nitrogen atom if X₅ corresponds to a carbon atom in the form of a carbene,
R″ and R′″, which may be the same or different at each occurrence, are hydrogen, halogen, NO₂, CN, NH₂, NHR⁵¹, N(R⁵¹)₂, B(OH)₂, B(OR⁵¹)₂, CHO, COOH, CONH₂, CON(R⁵¹)₂, CONHR⁵¹, SO₃H, C(═O)R⁵¹, P(═O)(R⁵¹)₂, S(═O)R⁵¹, S(═O)₂R⁵¹, P(R⁵¹)₃⁺, N(R⁵¹)₃⁺, OR⁵¹, SR⁵¹, Si(R⁵¹)₃, a straight chain alkyl or alkoxy group having 1 to 20 carbon atoms or a branched or cyclic alkyl or alkoxy group with 3 to 20 carbon atoms, a haloalkyl group, a substituted or unsubstituted aromatic or heteroaromatic ring system having 5 to 50 ring atoms or a substituted or unsubstituted aryloxy, heteroaryloxy or heteroarylamino group having 5 to 50 ring atoms,
two or more substituents R″ and R′″, either on the same or on different rings may define a further mono- or polycyclic, aliphatic or aromatic ring system with one another or with a substituent R⁵¹,
R⁵¹, which may be the same or different on each occurrence, may be hydrogen or a straight chain alkyl or alkoxy group having 1 to 20 carbon atoms or a branched or cyclic alkyl or alkoxy group with 3 to 20 carbon atoms, a substituted or unsubstituted aromatic or heteroaromatic ring system having 5 to 50 ring atoms or a substituted or unsubstituted aryloxy, heteroaryloxy or heteroarylamino group having 5 to 50 ring atoms, and a and b, independently from one another represent an integer in the range of from 0 to 3.

7. The light-emitting complex in accordance with claim 6, wherein at least one of the bidentate ligands units L¹ and L² is represented by formula (9).

8. The light-emitting complex in accordance with claim 6, wherein at least one of the bidentate ligands units L¹ and L² is represented by formula (10).

9. The light-emitting transition metal complex in accordance with claim 1, wherein at least one of the L¹ to L² bidentate ligand units is selected from the group consisting of phenylimidazole derivatives, phenylpyrazole derivatives, phenyltriazole derivatives, phenyltetrazole derivatives, 1-phenyl-imidazol-2-ylidene derivatives, 2-(1H-1,2,4-triazol-5-yl)pyridine derivatives, 2-(1H-pyrazol-5-yl)pyridine derivatives, phenylpyridine derivatives, phenylquinoline derivatives and phenylisoquinoline derivatives.

10. The light-emitting transition metal complex in accordance with claim 1, wherein at least one of the L¹ to L² bidentate ligand units is selected from the group consisting of compounds of formulae (11) to (26) 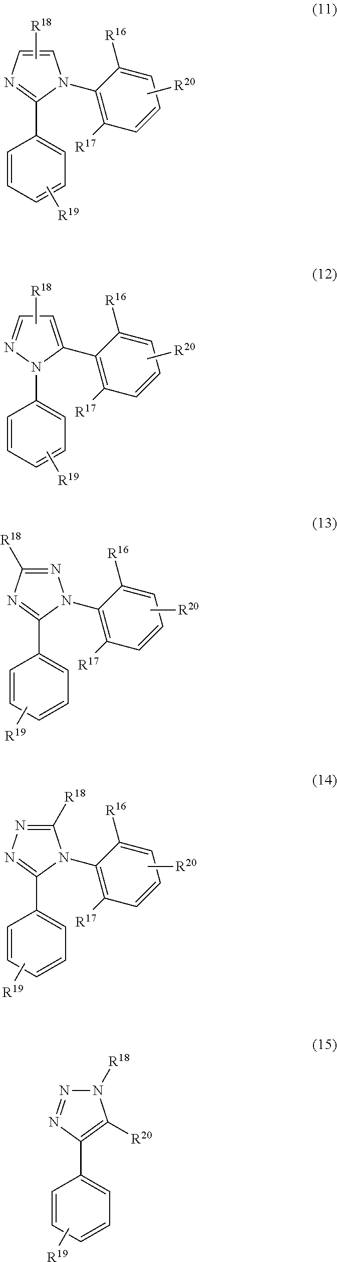
wherein R¹⁶ and R¹⁷ may be the same or different and are groups other than hydrogen selected from alkyl, haloalkyl, cycloalkyl, aryl and heteroaryl groups and wherein R¹⁸ to R²⁰ may be the same or different and may be selected from the group consisting of hydrogen, halogen, NO₂, CN, NH₂, NHR²¹, N(R²¹)₂, B(OH)₂, B(OR²¹)₂, CHO, COOH, CONH₂, CON(R²¹)₂, CONHR²¹, SO₃H, C(═O)R²¹, P(═O)(R²¹)₂, S(═O)R²¹, S(═O)₂R₂₁, P(R²¹)₃⁺, N(R²¹)₃⁺, OH, OR²¹, SR²¹, Si(R²¹)₃, and alkyl, haloalkyl, alkenyl, alkynyl, arylalkyl, aryl and heteroaryl groups, with R²¹ being selected from hydrogen, alkyl, aralkyl, aryl and heteroaryl groups, 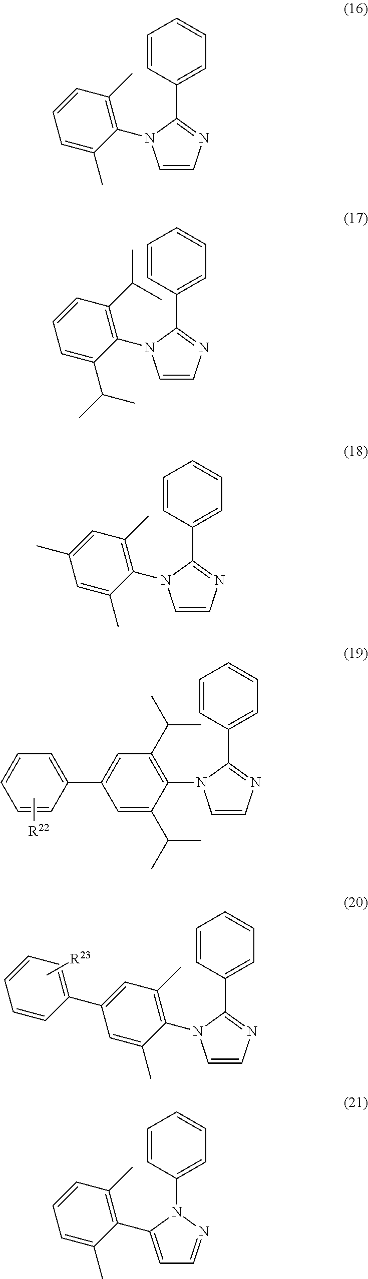 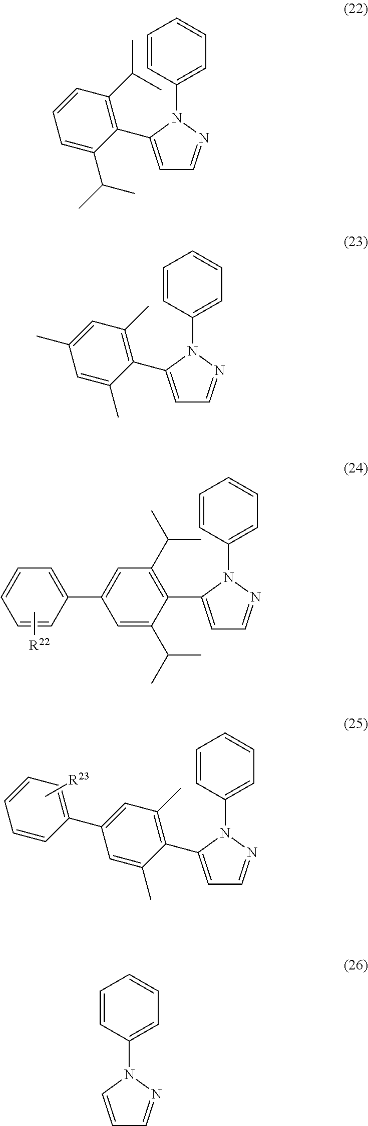
wherein R²² and R²³, independent of one another, are selected from hydrogen, halogen, NO₂, CN, NH₂, NHR²⁴, N(R²⁴)₂, B(OH)₂, B(OR²⁴)₂, CHO, COOH, CONH₂, CON(R²⁴)₂, CONHR²⁴, SO₃H, C(═O)R²⁴, P(═O)(R²⁴)₂, S(═O)R²⁴, S(═O)₂R²⁴, P(R²⁴)₃⁺, N(R²⁴)₃⁺, OH, OR²⁴, SR²⁴, Si(R²⁴)₃ and alkyl, haloalkyl, alkenyl, alkynyl, arylalkyl, aryl and heteroaryl group, with R²⁴ being selected from hydrogen, alkyl, aralkyl, aryl and heteroaryl groups.

11. The light-emitting transition metal complex in accordance with claim 1, wherein at least one of the L¹ to L² bidentate ligand units is selected from compounds of formulae (27) to (28): 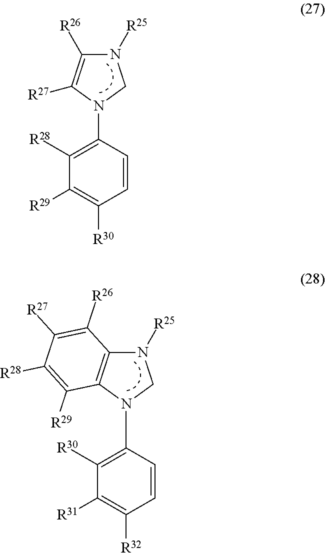
wherein R²⁵ to R³² may be the same or different at each occurrence and may be selected from the group consisting of hydrogen, halogen, NO₂, CN, NH₂, NHR³³, N(R³³)₂, B(OH)₂, B(OR³³)₂, CHO, COOH, CONH₂, CON(R³³)₂, CONHR³³, SO₃H, C(═O)R³³, P(═O)(R³³)₂, S(═O)R³³, S(═O)₂R³³, P(R³³)₃⁺, N(R³³)₃⁺, OH, OR³³, SR³³, Si(R³³)₃, and alkyl, haloalkyl, alkenyl, alkynyl, arylalkyl, aryl and heteroaryl groups, with R³³ being selected from hydrogen, alkyl, aralkyl, aryl and heteroaryl groups.

12. The light-emitting transition metal complex in accordance with claim 1, wherein at least one of the L¹ to L² bidentate ligand units is selected from compounds of formulae (29) to (30): 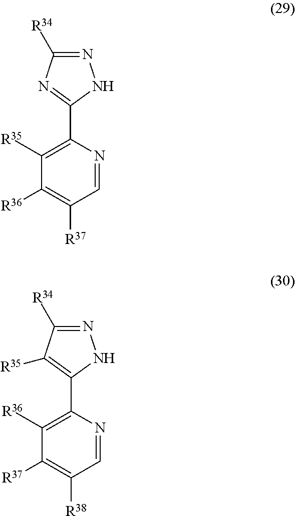
wherein R³⁴ to R³⁸ may be the same or different at each occurrence and may be selected from the group consisting of hydrogen, halogen, NO₂, CN, NH₂, NHR³⁹, N(R³⁹)₂, B(OH)₂, B(OR³⁹)₂, CHO, COOH, CONH₂, CON(R³⁹)₂, CONHR³⁹, SO₃H, C(═O)R³⁹, P(═O)(R³⁹)₂, S(═O)R³⁹, S(═O)₂R³⁹, P(R³⁹)₃⁺, N(R³⁹)₃⁺, OH, OR³⁹, SR³⁹, Si(R³⁹)₃, and alkyl, haloalkyl, alkoxy, alkenyl, alkynyl, arylalkyl, aryl and heteroaryl groups, with R³⁹ being selected from hydrogen, alkyl, aralkyl, aryl and heteroaryl groups.

13. The light-emitting transition metal complex in accordance with claim 1, wherein at least one of the L¹ to L² bidentate ligand units is selected from compounds of formulae 31 to 33 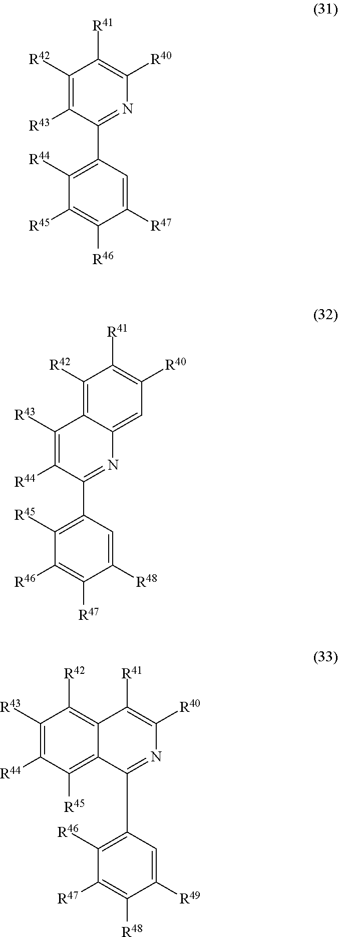
wherein R⁴⁰ to R⁴⁹ may be the same or different at each occurrence and may be selected from the group consisting of hydrogen, halogen, NO₂, CN, NH₂, NHR⁵⁰, N(R⁵⁰)₂, B(OH)₂, B(OR⁵⁰)₂, CHO, COOH, CONH₂, CON(R⁵⁰)₂, CONHR⁵⁰, SO₃H, C(═O)R⁵⁰, P(═O)(R⁵⁰)₂, S(═O)R⁵⁰, S(═O)₂R⁵⁰, P(R⁵⁰)₃⁺, N(R⁵⁰)₃⁺, OH, OR⁵⁰, SR⁵⁰, Si(R⁵⁰)₃, and alkyl, haloalkyl, alkoxy, alkenyl, alkynyl, arylalkyl, aryl and heteroaryl groups, with R⁵⁰ being selected from hydrogen, alkyl, aralkyl, aryl and heteroaryl groups.

14. The light-emitting transition metal complex in accordance with claim 1, comprising tetradentate ligands represented by formulae (L34) to (L40)

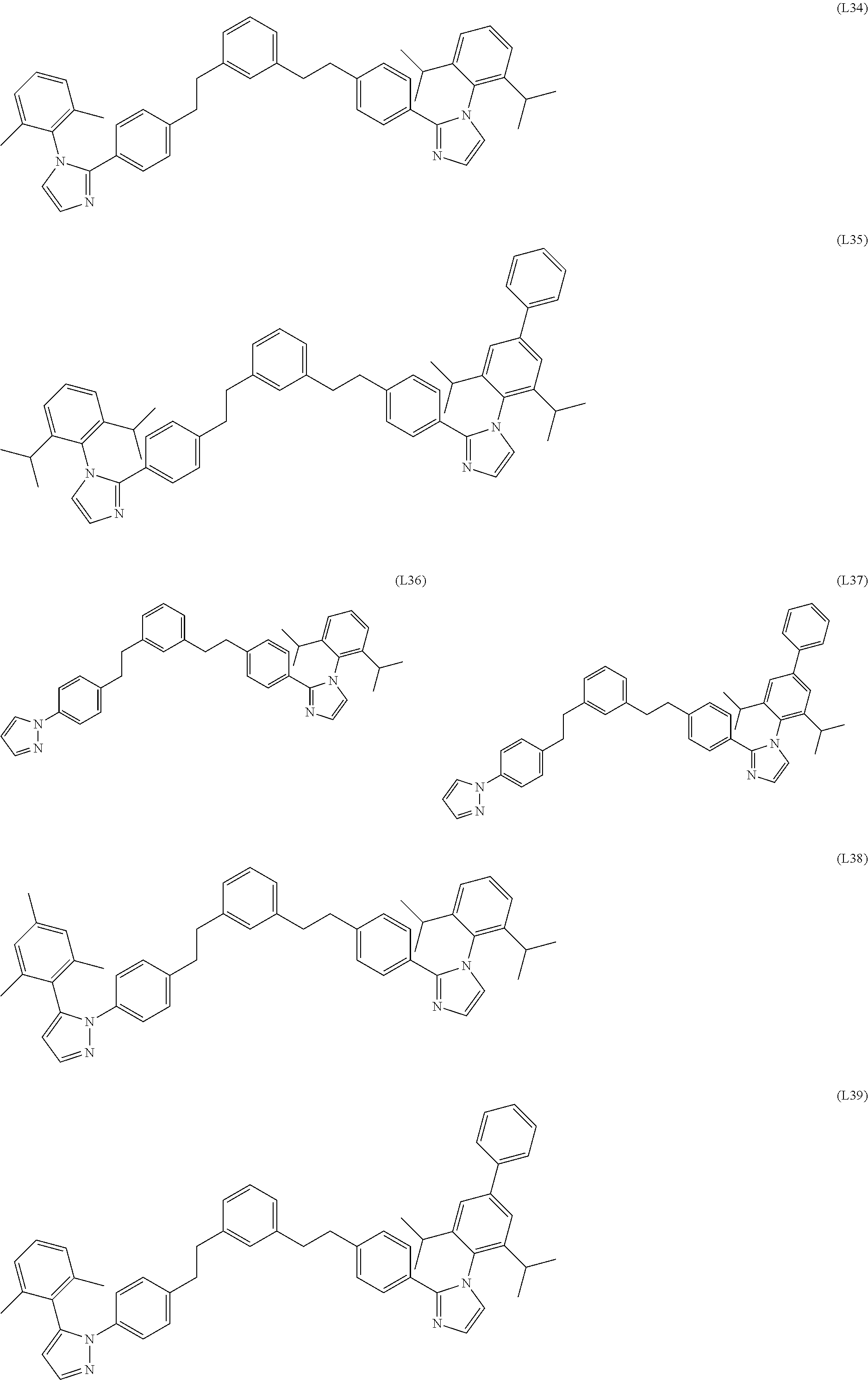

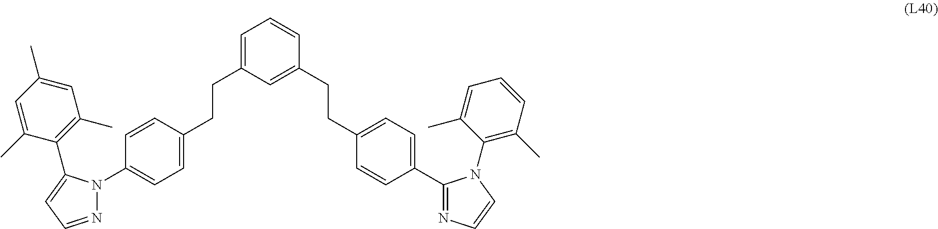

15. The light-emitting transition metal complex in accordance with claim 1, comprising an additional bidentate ligand L′ selected from ligands of formula (3′) 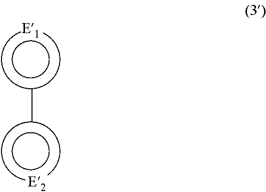
wherein
E′₁ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′₂, and
E₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′₁, and
wherein the rings E′₁ and E′₂ could together form a polycyclic aliphatic, aromatic or heteroaromatic ring system and
wherein the ring E′₁ is bound to the transition metal via a neutral donor atom which is a carbon in the form of a carbene or a heteroatom and the ring E′₂ is bound to the transition metal through a carbon atom having formally a negative charge or through a nitrogen atom having formally a negative charge.

16. The light-emitting transition metal complex in accordance with claim 1, comprising an additional bidentate ligand L′ selected from formulae (8) to (33).

17. The light-emitting transition metal complex in accordance with claim 1, comprising an additional bidentate ligand L′ selected from ligands of general formulae E3-SBF, E3-Ar1-SBF, E3-Open SBF and/or E3-Ar1-Open SBF wherein
E3 is a 5-membered heteroaryl ring, bound to the metal atom by covalent or dative bonds and containing at least one donor nitrogen atom, wherein said heteroaryl ring may be un-substituted or substituted by substituents selected from the group consisting of halogen, alkyl, alkoxy, amino, cyano, alkenyl, alkynyl, arylalkyl, aryl and heteroaryl group and/or may form an annealed ring system with other rings selected from cycloalkyl, aryl and heteroaryl rings;
Ar1 when present is bound to the metal atom by covalent or dative bonds and is selected from the group consisting of substituted or un-substituted C₆-C₃₀ arylene and substituted or un-substituted C₂-C₃₀ heteroarylene groups, which Ar1 group may be un-substituted or substituted by substituents selected from the group consisting of halogen, alkyl, alkoxy, amino, cyano, alkenyl, alkynyl, arylalkyl, aryl and heteroaryl groups;
SBF represents 9,9′-spirobifluorenyl, Open SBF represents 9,9-diphenyl-9H-fluorenyl, in both cases un-substituted or substituted by substituents selected from the group consisting of halogen, alkyl, alkoxy, amino, cyano, alkenyl, alkynyl, arylalkyl, aryl and heteroaryl groups or selected from picolinate, tetrakispyrazolylborate or acetylacetonate.

18. (canceled)

19. A layer suitable for forming the emissive layer of an organic light emitting device or a material with which an emissive layer of an organic light emitting device can be formed, said layer or said material comprising a light emitting transition metal complex in accordance with claim 1 as dopant with a host material, wherein the amount of the light emitting transition metal complex with respect to the total weight of the host and the dopant is at most 35% wt.

20. (canceled)

21. An organic light-emitting device comprising an emissive layer (EML), said emissive layer comprising a light-emitting transition metal complex or mixture thereof in accordance with claim 1, optionally with a host material.

22. The organic light emitting device in accordance with claim 21 wherein the emissive layer comprises the host material, the light emitting transition metal complex is present as dopant and the amount of the light emitting transition metal complex with respect to the total weight of the host and the dopant is at most 35% wt.
